(19) United States
(12) Patent Application Publication
(10) Pub. No.: US 2026/0150662 A1
(43) Pub. Date: May 28, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Che Wei YANG, New Taipei City (TW); Ming-Che LEE, Tainan City (TW); Sheng-Chan LI, Tainan City (TW); Wei-Hang HUANG, Tainan City (TW); Sheng-Chau CHEN, Tainan City (TW); Chung-Yi YU, Hsin-Chu (TW)

(21) Appl. No.: 18/960,447

(22) Filed: Nov. 26, 2024

(51) Int. Cl. H01L 23/522

(52) U.S. Cl. CPC H10W 20/496

(57) ABSTRACT

A semiconductor structure includes conductive electrode layers and an insulator layer that extend laterally into a plurality of dielectric layers. The lateral extensions may be referred to as fin portions. The fin portions may extend laterally outward from a central portion of a trench structure at a bottom section of the trench structure. The semiconductor structure may include a plurality of trench structures, and each trench structure may include a set of fin portions. In addition to the trench structures including the fin portions, the semiconductor structure may include additional trench structures located laterally between top sections of adjacent trench structures that include fin portions. The depth of the additional trench structures is less than a depth of the trench structures that include fin portions. This enables the fin portions to extend laterally under the additional trench structures, which enables the size of the fin portions to be increased.

### BACKGROUND

A semiconductor device may include one or more capacitor structures in an interconnect region above a device layer. A capacitor structure may perform and/or support one or more functions in the semiconductor device, such as memory (e.g., dynamic random access memory (DRAM)), charge decoupling, analog-to-digital (A/D) conversion, and/or other functions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of an example semiconductor device described herein.

FIGS. 2A-2E are diagrams of an example implementation of forming a semiconductor device described herein.

FIGS. 3A-3S are diagrams of an example implementation of forming a trench capacitor structure described herein.

FIG. 4 is a diagram of an example implementation of a portion of a capacitor structure described herein.

FIG. 5 is a diagram of an example semiconductor device described herein.

FIG. 6 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A capacitor structure may include a metal-insulator-metal (MIM) structure in which an insulator layer is sandwiched between two conductive electrode layers. The capacitance of the capacitor structure (e.g., the amount of charge that can be stored by the capacitor structure) is directly dependent on the geometry of the conductive electrode layers of the capacitor structure. The greater the area of the conductive electrode layers, the greater the capacitance of the capacitor structure. Thus, increasing the size of the metal electrode layers may increase the capacitance of the capacitor structure.

Increasing a lateral size of the capacitor structure is in direct contention with semiconductor design principles in the semiconductor industry, in which reducing semiconductor device sizes is pursued to achieve reduced power consumption, to achieve greater operating performance and efficiencies, and/or to enable semiconductor devices to be used in increasingly smaller form factor applications. Thus, in some cases, the size of a capacitor structure may be increased in a vertical direction in a semiconductor device such that the capacitor structure extends through a plurality of layers in the semiconductor device. A deep trench capacitor (DTC) is a type of capacitor structure that is formed in a deep trench in a semiconductor device such that the electrode layers and insulator layer extend along, and conform to, a profile of the deep trench. This enables the area of the conductive electrode layers to be increased (which increases the capacitance) with minimal increase in the lateral size of the capacitor structure. For example, capacitance may be calculated according to the following formula, where C is capacitance, εᵣ is a dielectric constant of the dielectric(s) in an insulator layer of a MIM structure, A is an effective capacitance area, and THK is a thickness of the insulator layer.

$$C = \frac{{ε}_{γ} A}{T H K}$$

The trench of a DTC structure is typically formed to have a high aspect ratio between the depth of the trench and the width of the trench. However, with increased miniaturization of semiconductor devices, areas of DTC structures may be limited and the increases in capacitance that the DTC structures provide may not necessarily be sufficient for some applications.

Some implementations described herein provide a DTC structure that extends through a plurality of dielectric layers in an interconnect region. The plurality of dielectric layers may be in an alternating arrangement. In addition, the conductive electrode layers and the insulator layer of the DTC structure may extend laterally into one or more of the dielectric layers. The lateral extensions of the conductive electrode layers and the insulator layer into the one or more dielectric layers may be referred to as fin portions of the DTC structure. The fin portions may extend laterally outward from a central portion of a trench structure at a bottom section of the trench structure.

The DTC structure may include a plurality of trench structures, and each trench structure may include a respective set of fin portions that extend laterally outward from the trench structure. In addition to the trench structures that include fin portions, in some implementations described herein, the DTC structure includes additional trench structures that are located laterally between top sections of adjacent trench structures that include fin portions. The depth of the additional trench structures is less than a depth of the trench structures that include fin portions. This enables the fin portions to extend laterally under the additional trench structures, which enables the size of the fin portions to be increased.

The fin portions and additional trench structures enable the surface area of the conductive electrode layers to be increased (e.g., relative to the conductive electrode layers in one type of trench structure extending vertically through the dielectric layers), which may increase the capacitance of the DTC structure with minimal increase to the overall footprint of the DTC structure. In this way, the trench structures including the fin portions at bottom sections thereof, and the additional trench structures interposed between the top sections of the trench structures including the fin portions, enable the size of the semiconductor device to be decreased, and/or the density of components in the semiconductor device to be increased, while achieving the same or greater capacitance for the DTC structures included in the semiconductor device. In some examples, the capacitance may be increased by about 10% to about 30%, when compared with DTC structures without the fin portions and/or the additional trench structures.

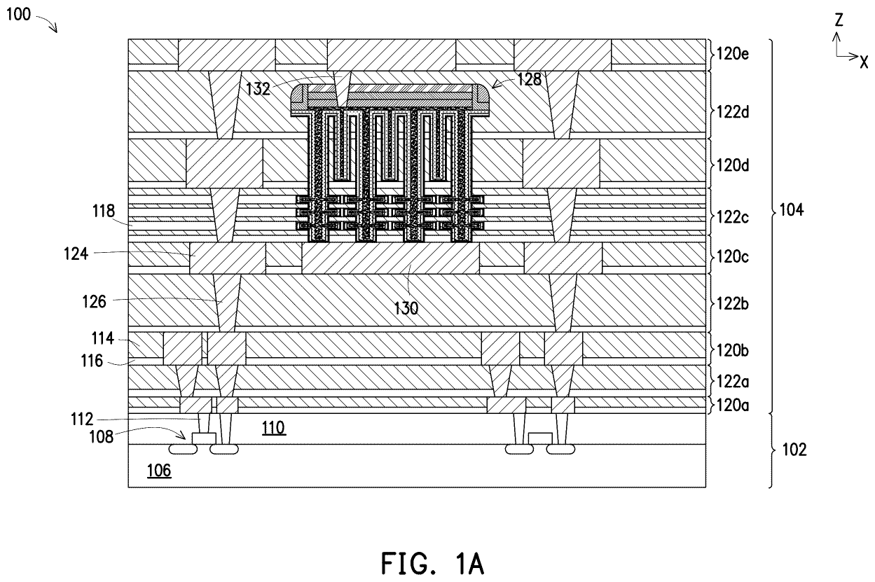

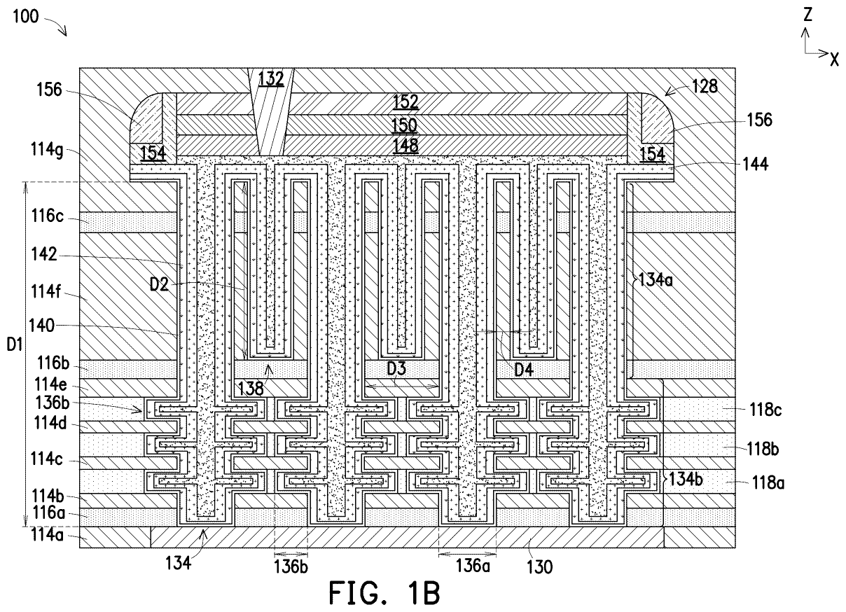

FIGS. 1A and 1B are diagrams of an example semiconductor device 100 described herein. The semiconductor device 100 may include a system on chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), and/or another type of semiconductor device.

FIG. 1A illustrates a cross-section view of the semiconductor device 100. As shown in FIG. 1A, the semiconductor device 100 may include a device layer 102 and an interconnect layer 104 arranged in a z-direction in the semiconductor device 100 the device layer 102. For example, the interconnect layer 104 may be located above the device layer 102. As another example, the interconnect layer 104 may be located below the device layer 102.

The interconnect layer 104 may include conductive structures that are arranged to carry signals and/or provide power distribution throughout the semiconductor device 100. In some implementations, the semiconductor device 100 includes interconnect layers 104 above and below the device layer 102. A first interconnect layer 104 on a first side of the device layer 102 may be used for signal propagation throughout the semiconductor device 100, and a second interconnect layer 104 on an opposing second side of the device layer 102 may be used for power distribution in the semiconductor device 100.

The device layer 102 includes a substrate 106 of the semiconductor device 100. The substrate 106 may correspond to a portion of a semiconductor wafer on which the semiconductor device 100 is formed. The substrate 106 may include a silicon (Si) substrate, a substrate formed of a material including silicon, a III-V compound semiconductor material substrate such as gallium arsenide (GaAs), a silicon on insulator (SOI) substrate, or another type of substrate. The substrate 106 may extend in an x-direction and/or in a y-direction in the semiconductor device 100 such that the top and bottom surfaces of the substrate 106 are approximately orthogonal to the z-direction in the semiconductor device 100.

Integrated circuit devices 108 may be included in and/or on the substrate 106 in the device layer 102 of the semiconductor device 100. The integrated circuit devices 108 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receives, optical circuits, and/or other types of front end semiconductor devices.

A front end transistor structure may include a plurality of source/drain regions, which may correspond to doped regions of the substrate 106, separated by a channel region in the substrate 106. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the integrated circuit devices 108 to be selectively etched or protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in the y-direction in the semiconductor device 100. Contacts 112 (e.g., source/drain contacts, gate contacts) may extend through the dielectric layer 110 and between the integrated circuit devices 108 and the interconnect layer 104. The contacts may electrically connect the integrated circuit devices 108 to the interconnect layer 104. The contacts 112 may include vias, plugs, and/or another type of elongated electrically conductive structures. The contacts 112 may include tungsten (W), cobalt (Co), ruthenium (Ru), titanium (Ti), aluminum (Al), and/or gold (Au), among other electrically conductive materials.

The interconnect layer 104 includes a plurality of dielectric layers (e.g., back end dielectric layers) that are arranged in a direction (e.g., the z-direction) that is approximately perpendicular to the top surface of the substrate 106. The dielectric layers may include ILD layers 114, ESLs 116, and dielectric film layers 118 that are arranged in an alternating manner in the z-direction. The ILD layers 114, the ESLs 116, and dielectric film layers 118 may extend in the x-direction and/or in the y-direction in the semiconductor device 100.

The ILD layers 114 may each include a low dielectric constant (low-k) oxide material such as silicon oxide (SiOₓ) or undoped silicate glass (USG). Additionally and/or alternatively, the ILD layers 114 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluorocthylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 116 and dielectric film layers 118 may each include a silicon nitride (SiₓN_{y}), silicon carbide (SiC), silicon oxynitride (SiON), silicon carbonitride (SiCN), silicon oxycarbonitride (SiCON), and/or another suitable dielectric material. In some implementations, an ILD layer 114 and an ESL 116, an ESL 116 and a dielectric film layer 118, and/or an ILD layer 114 and a dielectric film layer 118 include different dielectric materials to provide etch selectivity to enable various structures to be formed in the interconnect layer 104. For example, the ILD layers 114 may each include a low-k dielectric material such as silicon oxide (SiOₓ) or USG, and the ESLs 116 and dielectric film layers 118 may each include a high-k dielectric material such as silicon nitride (SiₓN_{y}) or silicon carbide (SiC). In some implementations, one or more of the ESLs 116 may include the same or similar materials as one or more of the ILD layers 114 where etch selectivity between the one or more ILD layers 114 and dielectric film layers 118, and between the one or more ESLs 116 and dielectric film layers 118 is needed. Additionally and/or alternatively, two or more ESLs 116 may include different materials. For example, one or more first ESLs 116 may include silicon nitride (SiₓN_{y}), and one or more second ESLs 116 may include silicon carbide (SIC).

In some implementations, the alternating arrangement of a plurality of ILD layers 114 with a plurality of dielectric film layers 118 is an alternating film structure, where the plurality of ILD layers 114 and the plurality of dielectric film layers 118 are alternately laminated on an underlying layer until a designated number of alternating ILD layers 114 and dielectric film layers 118 form the alternating film structure. In an example implementation, a layer of the alternating film structure is deposited on and bonded to an underlying layer using predetermined temperatures and pressures to bond the layers together. This process can be repeated until the alternating film structure includes the designated number of alternating ILD layers 114 and dielectric film layers 118. In some implementations, the lamination and/or bonding process is performed on the semiconductor device 100, and the alternating film structure is formed on an underlying ESL 116 of the semiconductor device 100 to result in the alternating film structure on the ESL 116 shown in FIG. 1A. Alternatively, the alternating film structure, including an alternating arrangement of a plurality of ILD layers 114 and a plurality of dielectric film layers 118, is formed separately and then bonded to the semiconductor device 100. For example, a pre-fabricated alternating film structure can be bonded to an underlying ESL 116 to result in the alternating film structure on the ESL 116 shown in FIG. 1A.

The interconnect layer 104 includes a plurality of conductive structures that are arranged in a plurality of layers. The conductive structures may be electrically coupled and/or physically coupled with one or more of the integrated circuit devices 108 in the device layer 102. The conductive structures provide electrical routing that enables signals and/or power to be provided to and/or from the integrated circuit devices 108.

The layers of conductive structures may include a plurality of layers 120a-120e that are vertically arranged and alternate with a plurality of layers 122a-122d in the z-direction (e.g., vertically alternate). The layers 120a-120e each include a layer of metallization structures 124, and the layers 122a-122d each include a layer of interconnect structures 126.

The layers 120a-120e of metallization structures 124 may be referred to as M-layers. For example, a layer 120a of metallization structures 124 (referred to as a metal-0 (M0) layer) may be located at the bottom of the interconnect layer 104 and may be coupled with the device layer 102. In particular, the metallization structures 124 in the M0 layer may be coupled with the contacts 112 (e.g., a contact layer referred to as “CO”-layer) of the integrated circuit devices 108 in the device layer 102. A layer 120b of metallization structures 124 (referred to as a metal-1 layer (M1) layer) may be located above the layer 120a of metallization structures 124 in the interconnect layer 104, a layer 120c of metallization structures 124 (referred to as a metal-2 layer (M2) layer) may be located above the layer 120b of metallization structures 124, and so on.

A layer 122a of interconnect structures 126 (referred to as a via-1 (V0) layer) may be included between the M0 layer and the M1 layer to interconnect the M0 layer and the M1 layer, a layer 122b of interconnect structures 126 (referred to as a via-2 (V1) layer) may be included between the M1 layer and the M2 layer to interconnect the M1 layer and the M2 layer, and so on.

The metallization structures 124 may include a combination of trenches, metallization layers, conductive traces, and/or other types of conductive structures. The interconnect structures 126 may include a combination of vias, interconnects, and/or other types of conductive structures. The metallization structures 124 and the interconnect structures 126 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 104 and the metallization structures 124, and/or between the dielectric layers of the interconnect layer 104 the interconnect structures 126. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., a topmost layer of metallization structures 124, a topmost layer of interconnect structures 126) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., a topmost layer of metallization structures 124, a topmost layer of interconnect structures 126) may be coupled to bonding structures, such as bonding pads and/or bonding vias.

As further shown in FIG. 1A, a trench capacitor structure 128 is included in the interconnect layer 104 of the semiconductor device 100. The trench capacitor structure 128 may extend through and/or may be included in one or more dielectric layers in the interconnect layer 104, such as one or more ILD layers 114, one or more ESLs 116, and/or one or more dielectric film layers 118. In some implementations, an integrated circuit device 108 is electrically coupled to a trench capacitor structure 128 to form a memory cell (e.g., a dynamic random access memory (DRAM) cell or another type of capacitor-based memory cell) in the semiconductor device 100. In some implementations, a trench capacitor structure 128 is configured to provide charge decoupling for one or more integrated circuit devices 108. In some implementations, a trench capacitor structure 128 is configured to store a charge (e.g., a photocurrent) for an integrated circuit device 108 (e.g., a pixel sensor) in the semiconductor device 100. In some implementations, a trench capacitor structure 128 is configured to perform another function in the semiconductor device 100.

The trench capacitor structure 128 may be electrically coupled and/or physically coupled to a bottom contact 130 at a bottom of the trench capacitor structure 128, and to a top contact 132 at a top of the trench capacitor structure 128. Alternatively, the trench capacitor structure 128 may be electrically coupled and/or physically coupled to a plurality of top contacts at the top of the trench capacitor structure 128. The bottom contact 130 and the top contact 132 may each include one or more conductive structures in the interconnect layer 104, such as one or more metallization structures 124 and/or one or more interconnect structures 126, among other examples.

FIG. 1B illustrates a detailed cross-section view of the trench capacitor structure 128. As shown in FIG. 1B, the trench capacitor structure 128 includes one or more first trench structures 134 on the bottom contact 130 (e.g., a metal contact). Each of the first trench structures 134 includes a top section 134a and a bottom section 134b under the top section 134a in the z-direction. Each of the first trench structures 134 includes a central portion 136a that extends through the top section 134a and the bottom section 134b. Each of the first trench structures 134 includes a plurality of fin portions 136b that extend laterally outward from the central portion 136a in the x-direction. The plurality of fin portions 136b extend from the central portion 136a at a bottom section 134b of each first trench structure 134. For each of the first trench structures 134, a first set of the plurality of fin portions 136b extend in the x-direction from a first side of the central portion 136a, and a second set of the plurality of fin portions 136b extend in the x-direction from a second side of the central portion 136a. For example, the first side can be opposite the second side, such as left and right sides (or front and back sides) of the central portion 136a.

In some implementations, a fin portion 136b is an extension from a side of the central portion 136a. The fin portion 136b can be a part of a continuous fin that wraps around the central portion 136a, where the continuous fin laterally extends from multiple sides (e.g., left, right, front, and/or back sides) of the central portion 136a. For example, a continuous fin may wrap 360 degrees (or 270 degrees, 180 degrees, etc.) around the central portion 136a, and a fin portion 136b may be a part of the continuous fin. Alternatively, a fin portion 136b may be a non-contiguous fin that laterally extends from one side or sides (e.g., left, right, front, or back side) of the central portion 136a.

In some implementations, the plurality of fin portions 136b are extended width regions, which extend a width of each of the plurality of first trench structures 134. For example, the plurality of fin portions 136b extend a width of each of the plurality of first trench structures 134 in the x-direction.

The bottom contact 130 may be included in an ILD layer 114a in the interconnect layer 104 of the semiconductor device 100. A first trench structure 134 of the trench capacitor structure 128 may extend through one or more dielectric layers in the interconnect layer 104 of the semiconductor device 100, including through an ESL 116a, an ILD layer 114b, a dielectric film layer 118a, an ILD layer 114c, a dielectric film layer 118b, an ILD layer 114d, a dielectric film layer 118c, an ILD layer 114c, an ESL 116b, an ILD layer 114f, an ESL 116c, and/or an ILD layer 114g, among other examples. In some implementations, the bottom contact 130 is below each of the first trench structures 134 in the z-direction, such that the bottom section 134b of each first trench structure 134 is adjacent to the bottom contact 130, and a bottom surface of each first trench structure 134 is on the bottom contact 130.

In some implementations, the first trench structure(s) 134 may have a high aspect ratio, which is a ratio of a depth (or height) (e.g., depth D1) of the first trench structure(s) 134 to a lateral width (or critical dimension) of the first trench structure(s) 134. Thus, the trench capacitor structure 128 may be referred to as a DTC structure. In some implementations, the aspect ratio of a first trench structure 134 may be approximately 10:1 or greater. In some implementations, a first trench structure 134 may have an aspect ratio that is included in the range of approximately 20:1 to approximately 50:1. However, other values and ranges are within the scope of the present disclosure.

As further shown in FIG. 1B, the trench capacitor structure 128 includes a plurality of second trench structures 138 (e.g., additional trench structures), which are located between the top sections 134a of adjacent first trench structures 134. Each second trench structure 138 is laterally adjacent to a side of an adjacent first trench structure 134 in the x-direction. As can be seen in FIG. 1B, each second trench structure 138 is adjacent to two first trench structures 134 on opposite sides of the second trench structure 138. In some cases, depending on the location of the second trench structure 138 and the total number of first trench structures 134 and second trench structures 138, a second trench structure 138 may be adjacent to one first trench structure 134.

A depth D2 (or height) of each second trench structure 138 is less than a depth D1 (or height) of each first trench structure 134. As can be seen in FIG. 1B, each second trench structure 138 is adjacent to the top sections 134a of the first trench structures 134 and does not extend below the top sections 134a of the first trench structures 134. In addition, as can be seen in FIG. 1B, the bottom surfaces of the second trench structures 138 are on an ESL 116b, and above the plurality of fin portions 136b (e.g., at a higher vertical/z-direction position in the semiconductor device 100 than the plurality of fin portions 136b). The ESL 116b on which the bottom surfaces of the second trench structures 138 are disposed is also above the plurality of fin portions 136b.

Each of the second trench structures 138 has a linear profile along the depth D2 of the second trench structures 138 from a top of the second trench structure 138 to a bottom of the second trench structure 138.

As further shown in FIG. 1B, the trench capacitor structure 128 includes a plurality of conformal layers that conform to the profile of the first trench structure(s) 134 and second trench structures 138. The conformal layers may include an adhesion layer 140, a bottom electrode layer 142 on the adhesion layer 140, and an insulator layer 144 on the bottom electrode layer 142. The adhesion layer 140, the bottom electrode layer 142, and the insulator layer 144 may each conform to the profile of the first trench structure(s) 134 and second trench structures 138 such that the adhesion layer 140, the bottom electrode layer 142, and the insulator layer 144 conform to the sidewalls, fin portion surfaces, and the bottom surfaces of the first trench structure(s) 134, and to the sidewalls and the bottom surfaces of the second trench structures 138. The trench capacitor structure 128 further includes a top electrode layer 146 on the insulator layer 144. In some implementations, the top electrode layer 146 is a fill layer that fills in the remaining areas of the first trench structure(s) 134 and the second trench structures 138, and is a conformal layer that conforms to the sidewalls, fin portion surfaces, and the bottom surfaces of the first trench structure(s) 134, and to the sidewalls and the bottom surfaces of the second trench structures 138. Alternatively, the top electrode layer 146 may be a conformal layer that conforms to the sidewalls, fin portion surfaces, and the bottom surfaces of the first trench structure(s) 134, and to the sidewalls and the bottom surfaces of the second trench structures 138, and a dielectric plug layer or fill layer is further included in the remaining areas of the first trench structure(s) 134 and the second trench structures 138.

In some implementations, the adhesion layer 140, the bottom electrode layer 142, the insulator layer 144, and the top electrode layer 146 continuously extend from the plurality of first trench structures 134 to the plurality of second trench structures 138. The adhesion layer 140, the bottom electrode layer 142, the insulator layer 144, and the top electrode layer 146 may be continuous throughout the plurality of first trench structures 134 to the plurality of second trench structures 138.

The adhesion layer 140 may also be referred to as a glue layer, and may be included to promote adhesion of the bottom electrode layer 142 to the dielectric layers (e.g., the ILD layers 114b, 114c, 114d, 114c, 114f, and 114g, the ESLs 116a, 116b, and 116c, the dielectric film layers 118a, 118b, and 118c) and/or to the bottom contact 130. The adhesion layer 140 may also act as a barrier layer that prevents upward migration of an electrically conductive material (e.g., copper (Cu)) of the bottom contact 130 into the bottom electrode layer 142. The adhesion layer 140 may include tantalum (Ta), tantalum nitride (TaN), and/or another suitable adhesion material.

The bottom electrode layer 142, the insulator layer 144, and the top electrode layer 146 correspond to an MIM structure of the trench capacitor structure 128. Thus, the trench capacitor structure 128 may also be referred to as an MIM capacitor structure. The bottom electrode layer 142 (also referred to as a capacitor bottom metal (CBM)) and the top electrode layer 146 (also referred to as a capacitor top metal (CTM)) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), aluminum (Al), copper (Cu), gold (Au), titanium nitride (TiN), and/or tantalum nitride (TaN), among other examples. In some implementations, the bottom electrode layer 142 and the top electrode layer 146 include the same material or the same material composition. In some implementations, the bottom electrode layer 142 and the top electrode layer 146 include different materials or different material compositions.

The insulator layer 144 may include one or more electrically insulating materials. In some implementations, the insulator layer 144 includes one or more low-k dielectric materials such as silicon oxide (SiOₓ such as SiO₂). Additionally and/or alternatively, the insulator layer 144 may include one or more high-k dielectric materials such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the insulator layer 144 is a multiple-layer stack that includes a plurality of dielectric layers. For example, the insulator layer 144 may include a ZrO₂/Al₂O₃/ZrO₂ (ZAZ) layer stack. In an effort to reduce or prevent the migration of oxygen from the zirconium oxide layers of the ZrO₂/Al₂O₃/ZrO₂ (ZAZ) layer stack to the bottom electrode layer 142, a nitrous oxide (N₂O) surface treatment of the bottom electrode layer 142 may be performed, which creates an interlayer between the insulator layer 144 and the bottom electrode layer 142. The interlayer acts as an oxygen diffusion barrier layer between the bottom electrode layer 142 and the lower zirconium oxide layer of the ZrO₂/Al₂O₃/ZrO₂ (ZAZ) layer stack. The interlayer may be an oxide and/or oxynitride of the metal of the bottom electrode layer 142. For example, the interlayer may include titanium oxide (e.g., TiOₓ such as TiO₂) and/or titanium oxynitride (TiOₓN_{y}).

The dielectric constant of zirconium oxide is greater than the dielectric constant of aluminum oxide. A combined thickness of the zirconium oxide layers that is greater than the thickness of the aluminum oxide layer in the ZrO₂/Al₂O₃/ZrO₂ (ZAZ) layer stack provides an insulator layer 144 that includes a greater amount of zirconium oxide than aluminum oxide, which enables a higher overall dielectric constant to be achieved for the insulator layer 144, which enables a greater capacitance to be achieved for the trench capacitor structure 128 in which the insulator layer 144 is included. Since the band gap of aluminum oxide (AlₓO_{y} such as Al₂O₃) (e.g., approximately 8.9 electron volts (eV)) is higher than the band gap of zirconium oxide (ZrOₓ such as ZrO₂) (e.g., approximately 5.8 electron volts (eV)), the aluminum oxide layer in the ZrO₂/Al₂O₃/ZrO₂ (ZAZ) layer stack acts a leakage barrier for higher breakdown voltages.

In some implementations, the trench capacitor structure 128 includes a plurality of first trench structures 134 and a plurality of second trench structures 138, and the MIM structure of the trench capacitor structure 128 (e.g., the bottom electrode layer 142, the insulator layer 144, and the top electrode layer 146) may extend along the sidewalls, fin portion surfaces, and bottom surfaces of the plurality of first trench structures 134, along the sidewalls and bottom surfaces of the plurality of second trench structures 138, and between the plurality of first trench structures 134 and the plurality of second trench structures 138. The first trench structures 134 may be laterally arranged and spaced apart by a distance (indicated in FIG. 1B as dimension D3) in the x-direction. The second trench structures 138 may be laterally arranged between the first trench structures 134 and spaced apart from the first trench structures 134 by a distance (indicated in FIG. 1B as dimension D4) in the x-direction. In this way, including the plurality of first trench structures 134 and the plurality of second trench structures 138 in the trench capacitor structure 128 enables the length (and therefore the area) of the MIM structure of the trench capacitor structure 128 (e.g., of the bottom electrode layer 142, the insulator layer 144, and the top electrode layer 146) to be extended, thereby increasing the capacitance of the trench capacitor structure 128. The inclusion of the fin portions 136b in the bottom sections 134b of the plurality of first trench structures 134 further enables the area of the MIM structure of the trench capacitor structure 128 (e.g., of the bottom electrode layer 142, the insulator layer 144, and the top electrode layer 146) to be extended, thereby increasing the capacitance of the trench capacitor structure 128.

As further shown in FIG. 1B, the trench capacitor structure 128 may include one or more capping layers above the first trench structure(s) 134, above the second trench structures 138, and above the MIM structure of the trench capacitor structure 128. The one or more capping layers may include an oxide capping layer 148, an oxynitride capping layer 150, and/or a nitride capping layer 152, among other examples. The capping layers may provide electrical isolation for the MIM structure of the trench capacitor structure 128, and/or may also function as a hard mask layer stack for forming the top contact 132. The oxide capping layer 148 may include an oxide-containing dielectric material such as silicon oxide (SiOₓ such as SiO₂), among other examples. The oxynitride capping layer 150 may include an oxynitride-containing dielectric material such as silicon oxynitride (SiON), among other examples. The nitride capping layer 152 may include a nitride-containing dielectric material such as silicon nitride (SiₓN_{y} such as Si₃N₄), among other examples.

As further shown in FIG. 1B, the trench capacitor structure 128 may include one or more sidewall spacers 154 and/or 156 on the sidewalls of the capping layers 148-152 and/or on sidewalls of the top electrode layer 146 that is above the first trench structure(s) 134, and above the second trench structures 138. The combination of the capping layers 148-152 and the sidewall spacers 154 and 156 may be used as a self-aligned mask when etching the adhesion layer 140, the bottom electrode layer 142, the insulator layer 144, and/or the top electrode layer 146 to define the MIM structure of the trench capacitor structure 128. The sidewall spacer 154 may include an oxide-containing dielectric material such as silicon oxide (SiOₓ such as SiO₂), among other examples. The sidewall spacer 156 may include a nitride-containing dielectric material such as silicon nitride (SiₓN_{y} such as Si₃N₄), among other examples.

As indicated above, FIGS. 1A and 1B are provided as an example. Other examples may differ from what is described with regard to FIGS. 1A and 1B.

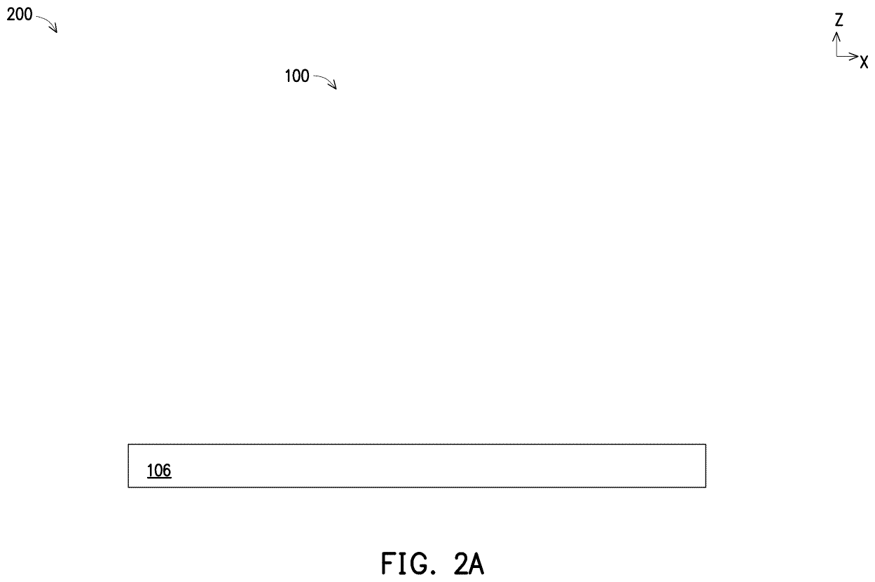

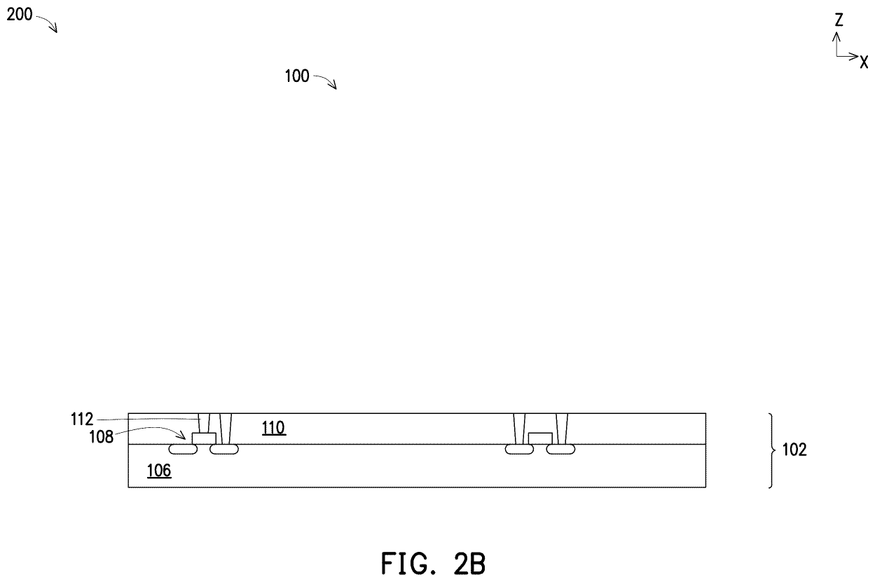

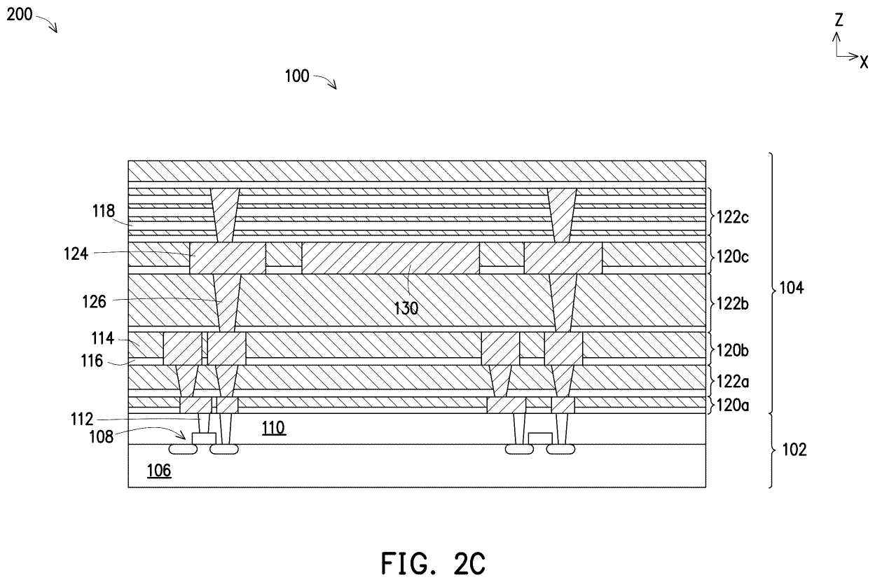

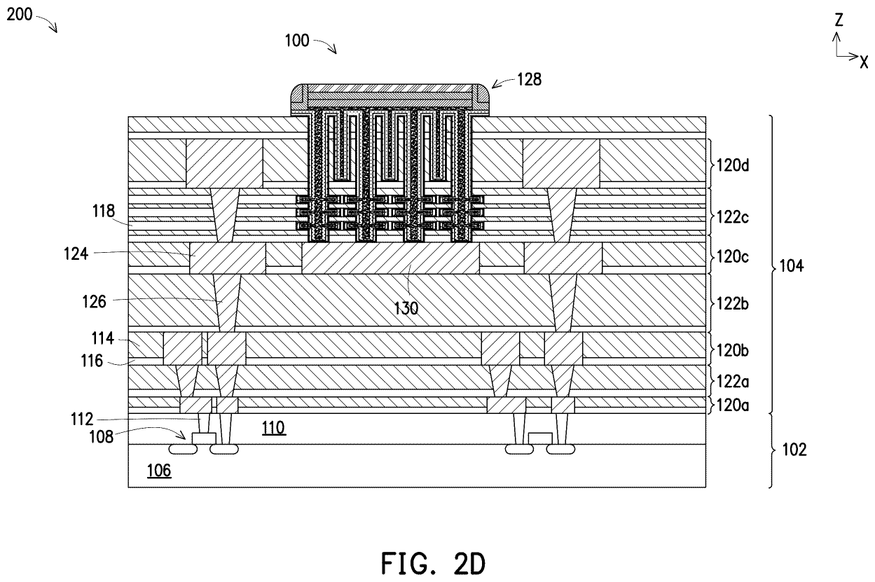

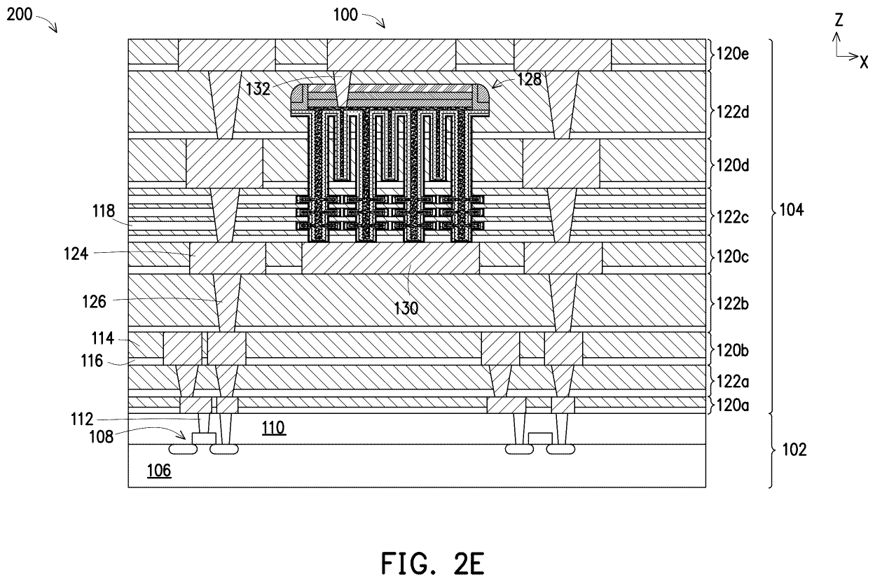

FIGS. 2A-2E are diagrams of an example implementation 200 of forming the semiconductor device 100 described herein. In some implementations, one or more of the semiconductor processing operations described in connection with FIGS. 2A-2E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 2A, the substrate 106 is provided. The substrate 106 may be provided in the form of a semiconductor wafer such as a silicon (Si) wafer, an SOI wafer, and/or another type of semiconductor work piece. The semiconductor device 100 may be formed on the semiconductor wafer with other semiconductor devices.

As shown in FIG. 2B, the integrated circuit devices 108 may be formed in and/or on the substrate 106 in the device layer 102 of the semiconductor device 100. One or more semiconductor processing tools may be used to form one or more portions of the integrated circuit devices 108. For example, an ion implantation tool may be used to dope one or more regions in the substrate 106 with one or more types of dopants to form well regions, implant regions, and/or other types of doped regions in the substrate 106 for the integrated circuit devices 108. As another example, a deposition tool may be used to perform various deposition operations to deposit layers and/or structures of the integrated circuit devices 108, and/or to deposit photoresist layers for etching the substrate 106 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the integrated circuit devices 108. As another example, a planarization tool may be used to planarize portions of the integrated circuit devices 108. As another example, a plating tool may be used to deposit metal structures and/or layers of the integrated circuit devices 108.

As further in FIG. 2B, a deposition tool is used to deposit the dielectric layer 110 over and/or on the substrate 106 and over and/or on the integrated circuit devices 108. A deposition tool may be used to deposit the dielectric layer 110 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 110 after the dielectric layer 110 is deposited.

As further shown in FIG. 2B, the contacts 112 of the integrated circuit devices 108 may be formed through the dielectric layer 110. The contacts 112 may be formed in recesses in the dielectric layer 110. In some implementations, a pattern in a photoresist layer is used to etch the dielectric layer 110 to form the recesses. In these implementations, a deposition tool may be used to form the photoresist layer on the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 110 based on a pattern to form the recesses.

The contacts 112 may be formed in the recesses. In some implementations, a contact 112 (e.g., a gate contact) is formed on a gate structure of an integrated circuit device 108. In some implementations, a contact 112 (e.g., a source/drain contact) is formed on a source/drain region of an integrated circuit device 108. A deposition tool may be used to deposit the material of the contacts 112 in the recesses using a CVD technique, a PVD technique, an ALD technique, an electroplating technique, and/or another suitable deposition technique. The material of the contacts 112 may be deposited in one or more deposition operations. In some implementations, a seed layer is first deposited, and the material of the contacts 112 is deposited on the seed layer. In some implementations, a planarization tool is used to perform a planarization operation (e.g., a CMP operation) to planarize the contacts 112 after the contacts 112 are deposited such that the tops of the contacts 112 are approximately co-planar with the top of the dielectric layer 110.

As shown in FIG. 2C, a first portion of the interconnect layer 104 of the semiconductor device 100 is formed above the dielectric layer 110. One or more deposition tools are used to deposit alternating layers of ILD layers 114 and ESLs 116, and alternating layers of ILD layers 114 and dielectric film layers 118 in the first portion of the interconnect layer 104 of the semiconductor device 100. In this way, the ILD layers 114, ESLs 116, and dielectric film layers 118 may be arranged in the z-direction in the semiconductor device 100. One or more deposition tools may be used to deposit each of the ILD layers 114, each of the ESLs 116, and each of the dielectric film layers 118 using a PVD technique, an ALD technique, a CVD technique, an oxidation technique, and/or another suitable deposition technique. In some implementations, a planarization tool may be used to planarize the ILD layers 114, the ESLs 116, and/or the dielectric film layers 118 after the ILD layers 114, the ESLs 116, and/or the dielectric film layers 118 are deposited.

As noted herein, in some implementations, as an alternative to using deposition techniques to form the alternating arrangement of the plurality of ILD layers 114 and the plurality of dielectric film layers 118, the alternating arrangement of the plurality of ILD layers 114 with the plurality of dielectric film layers 118 may be an alternating film structure. In this implementation, the plurality of ILD layers 114 and the plurality of dielectric film layers 118 are alternately laminated on an underlying layer until a designated number of alternating ILD layers 114 (e.g., four ILD layers 114) and dielectric film layers 118 (e.g., three dielectric film layers 118) form the alternating film structure. For example, a first dielectric film layer 118 is deposited on and bonded to a first ILD layer 114 using a predetermined temperature and pressure to bond the first dielectric film layer 118 to the first ILD layer 114. Then, a second ILD layer 114 is deposited on and bonded to the first dielectric film layer 118 using a predetermined temperature and pressure to bond the second ILD layer 114 to the first dielectric film layer 118. Then, a second dielectric film layer 118 is deposited on and bonded to a second ILD layer 114 using a predetermined temperature and pressure to bond the second dielectric film layer 118 to the second ILD layer 114. This process can be repeated until the alternating film structure includes the designated number of alternating ILD layers 114 and dielectric film layers 118. The lamination and/or bonding process can be performed on the semiconductor device 100 starting with the first ILD layer of the alternating film structure being formed on an underlying ESL 116 of the semiconductor device 100, and then continued until the completed alternating film structure is formed on the ESL 116, as shown in FIG. 2C. Alternatively, the alternating film structure, including the alternating arrangement of ILD layers 114 and dielectric film layers 118, is formed separately and then bonded to the semiconductor device 100. The pre-fabricated alternating film structure can be bonded to an underlying ESL 116 to result in the alternating film structure on the ESL 116 shown in FIG. 2C. Bonding the pre-fabricated alternating film structure to the underlying ESL 116 may be performed by using an adhesive to bond the dielectric material of the first ILD layer to 114 to the underlying ESL 116.

Thicknesses in the z-direction of the ILD layers 114 and the dielectric film layers 118 in the alternating arrangement of ILD layers 114 and dielectric film layers 118 may be approximately the same as each other, and may be approximately 100 angstroms to approximately 5000 angstroms. However, other values and ranges are within the scope of the present disclosure.

One or more deposition tools may be used to deposit an ESL 116 on the topmost ILD layer 114 of the alternating film structure using a PVD technique, an ALD technique, a CVD technique, an oxidation technique, and/or another suitable deposition technique.

As further shown in FIGS. 2C, a deposition tool, an exposure tool, a developer tool, an etch tool, a planarization tool, a plating tool, and/or another semiconductor processing tool may be used to perform various operations to form the metallization structures 124 and to form the interconnect structures 126 in the first portion of the interconnect layer 104 of the semiconductor device 100. The bottom contact 130 of the trench capacitor structure 128 may also be formed in the first portion of the interconnect layer 104.

In some implementations, the first portion of the interconnect layer 104 may be formed in a plurality of layers. For example, an ILD layer 114 and an ESL 116 may be formed (e.g., using one or more deposition tools and/or one or more planarization tools), recesses may be formed in and/or through the ILD layer 114 and the ESL 116 (e.g., using an exposure tool, a developer tool, and/or an etch tool), and the layer 120a (e.g., the M0 layer) of metallization structures 124 may be formed in the ILD layer 114 and the ESL 116 (e.g., using one or more deposition tools and/or one or more planarization tools). Another ILD layer 114 and another ESL 116 may be formed, and the layer 122a (e.g., the V0 layer) of interconnect structures 126 may be formed in the ILD layer 114 and the ESL 116. The layers 120b, 120c, 122b, and 122c may be formed in a similar manner. For example, an ESL 116 and the stacked alternating arrangement of ILD layers 114 and dielectric film layers 118 may be formed (e.g., using one or more deposition tools, one or more lamination processes, one or more bonding processes, and/or one or more planarization tools), recesses may be formed in and/or through the ESL 116 and the stacked alternating arrangement of ILD layers 114 and dielectric film layers 118 (e.g., using an exposure tool, a developer tool, and/or an etch tool), and the layer 122c (e.g., the V2 layer where the layer 122b is the V1 layer) of metallization structures 124 may be formed in the ESL 116 and the alternating arrangement of ILD layers 114 and dielectric film layers 118 (e.g., using one or more deposition tools and/or one or more planarization tools).

One or more deposition tools may be used to deposit the metallization structures 124, the interconnect structures 126, and/or the bottom contact 130 using a PVD technique, an ALD technique, a CVD technique, an electroplating technique (e.g., an electro-chemical plating technique), and/or another suitable deposition technique. In some implementations, a planarization tool may be used to planarize the metallization structures 124, the interconnect structures 126, and/or the bottom contact 130 after the metallization structures 124, the interconnect structures 126, and/or the bottom contact 130 are deposited.

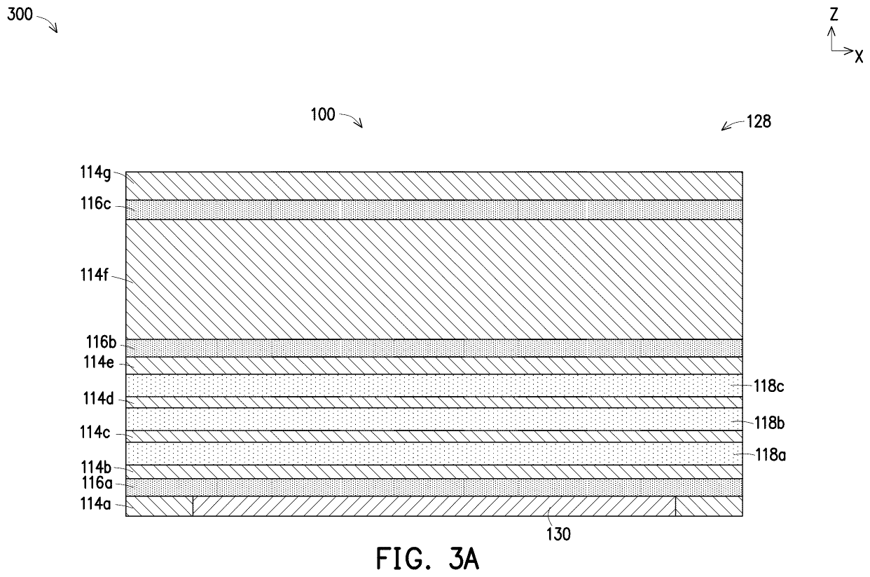

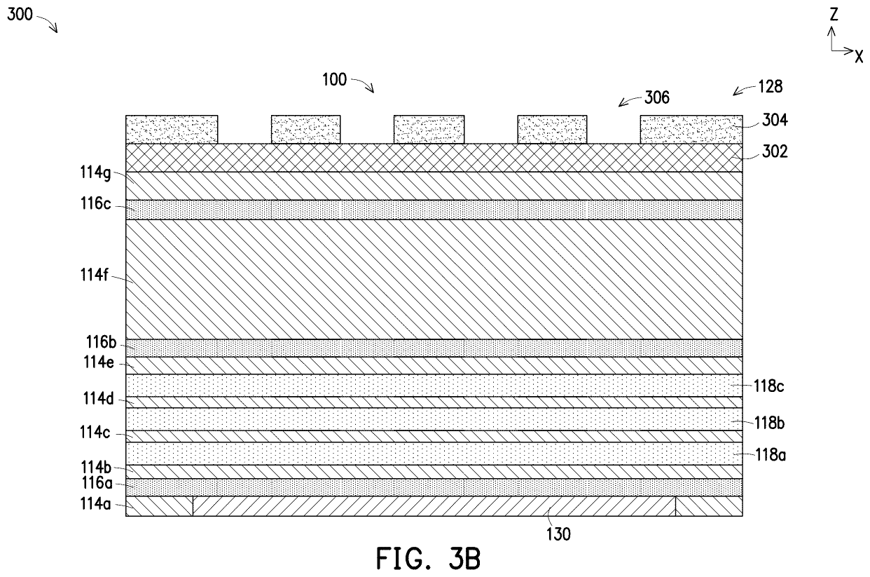

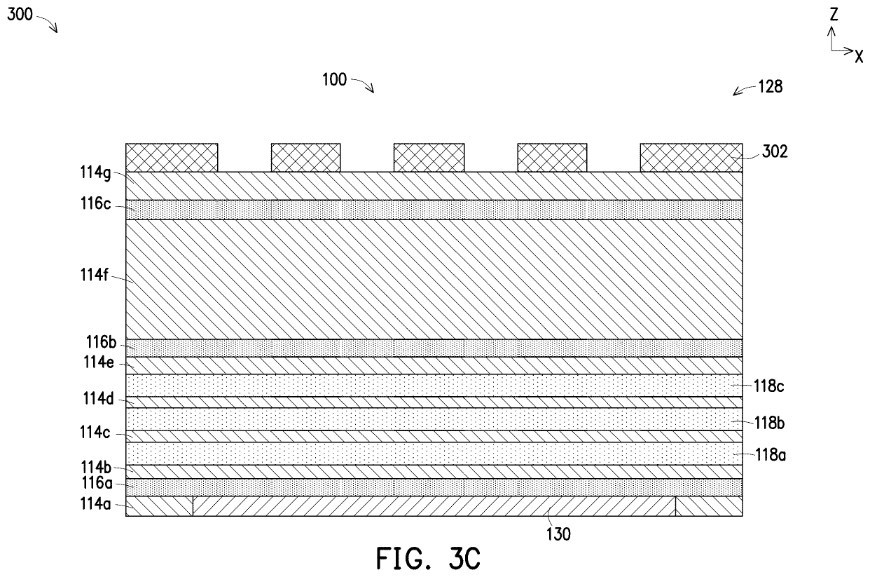

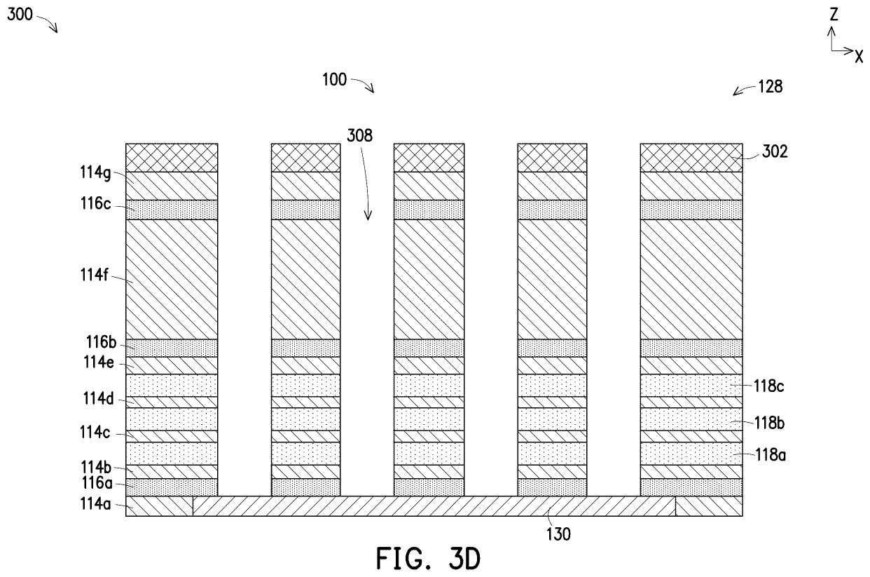

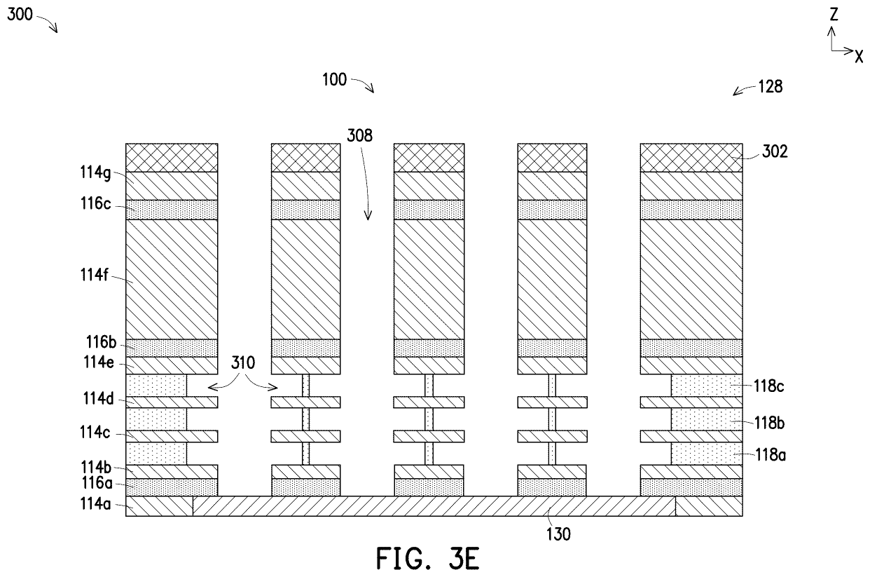

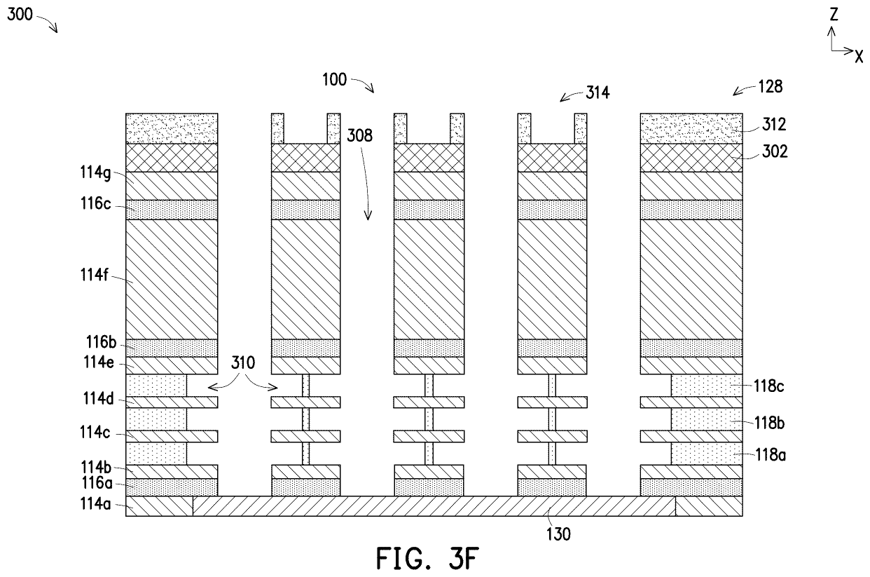

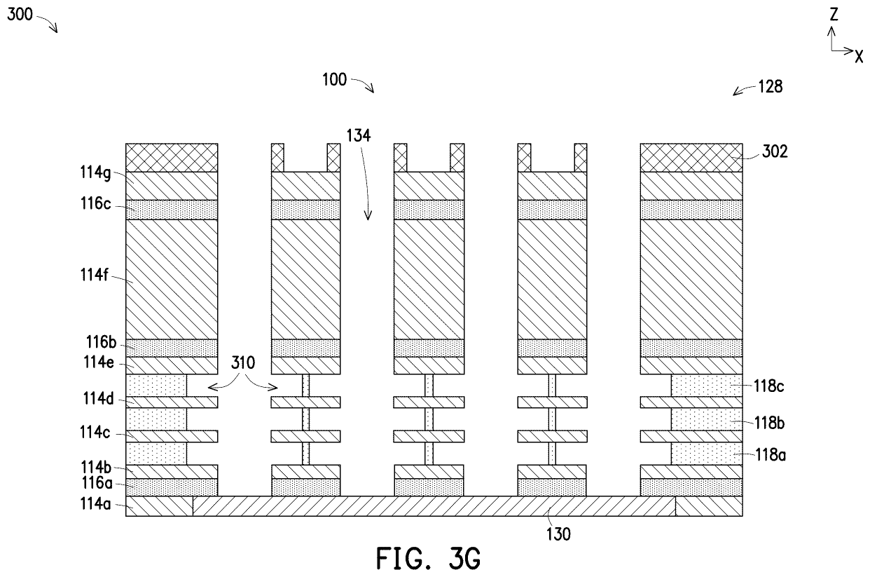

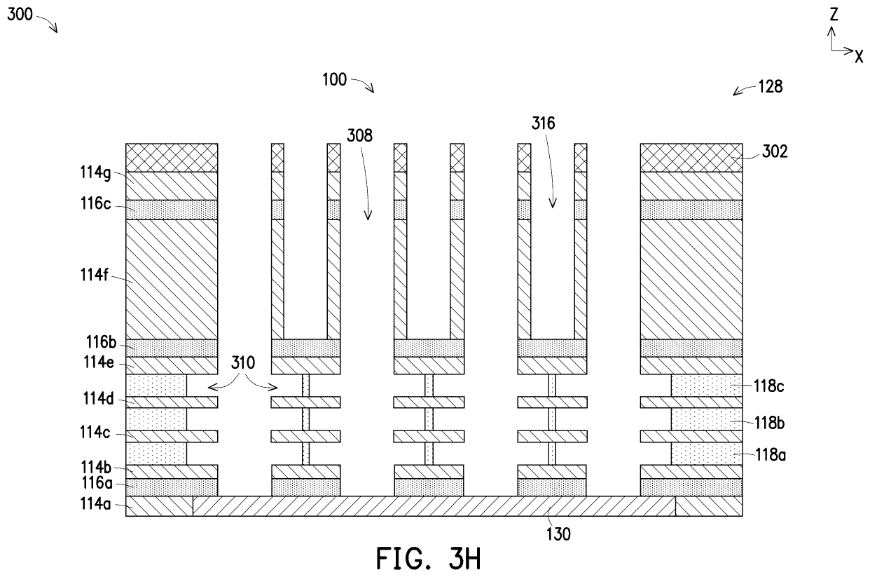

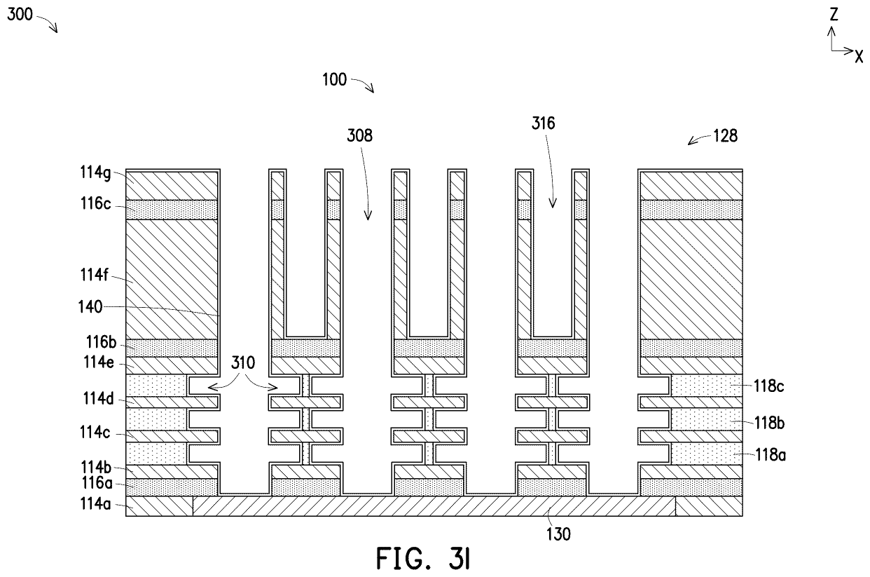

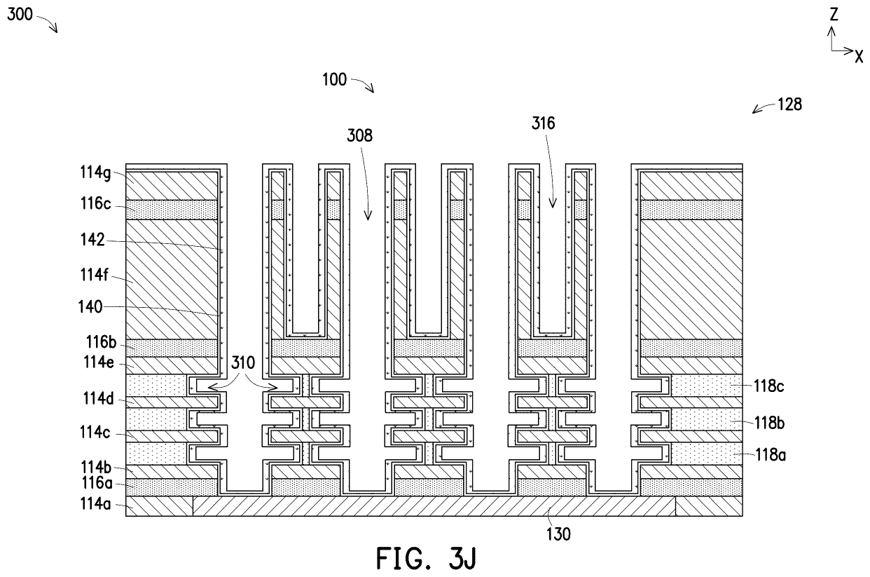

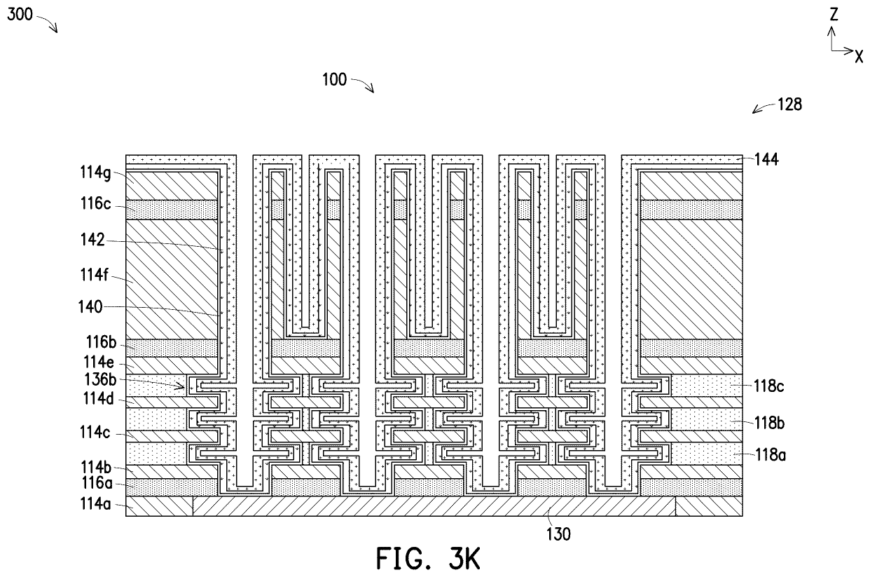

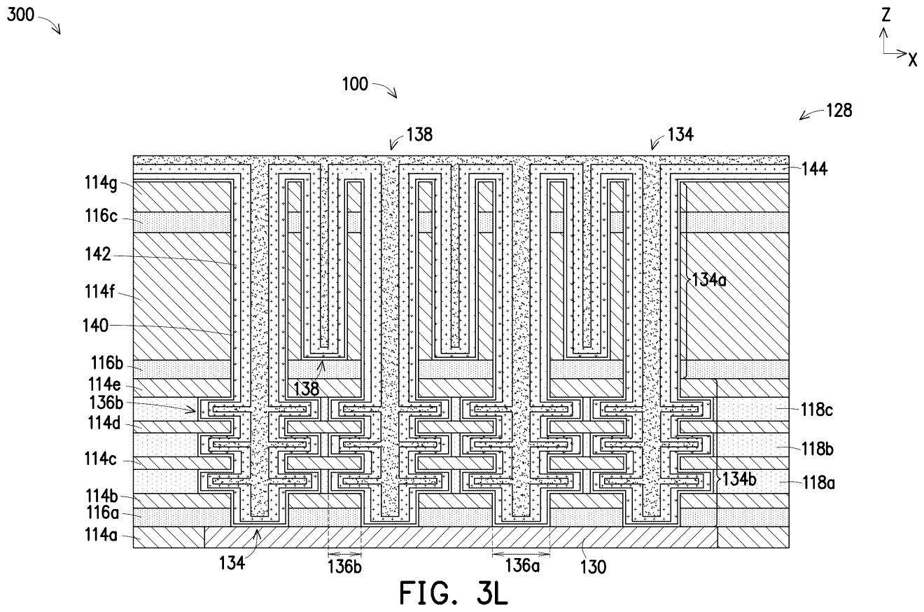

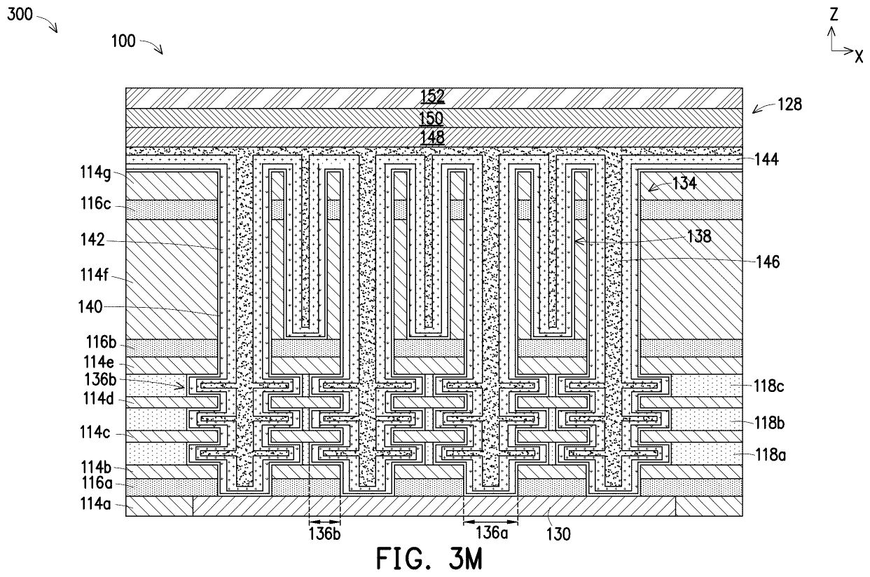

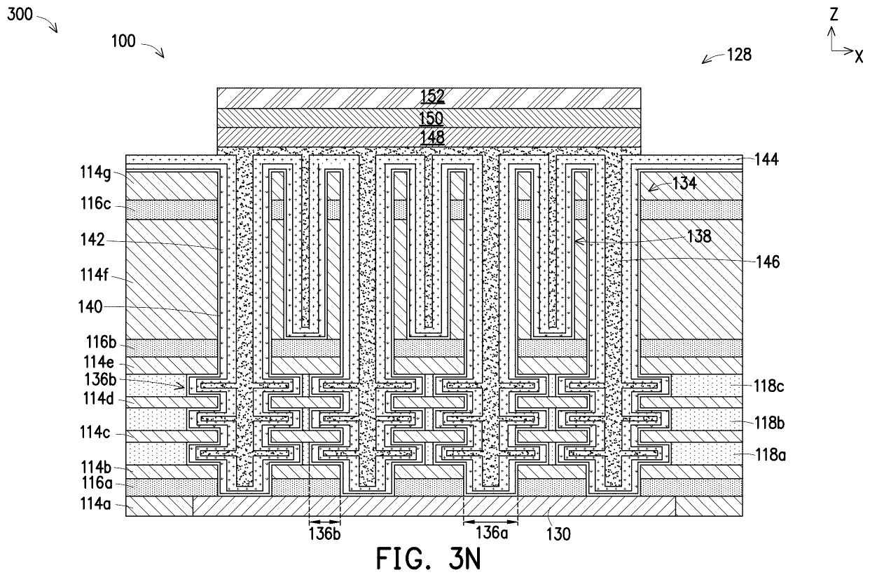

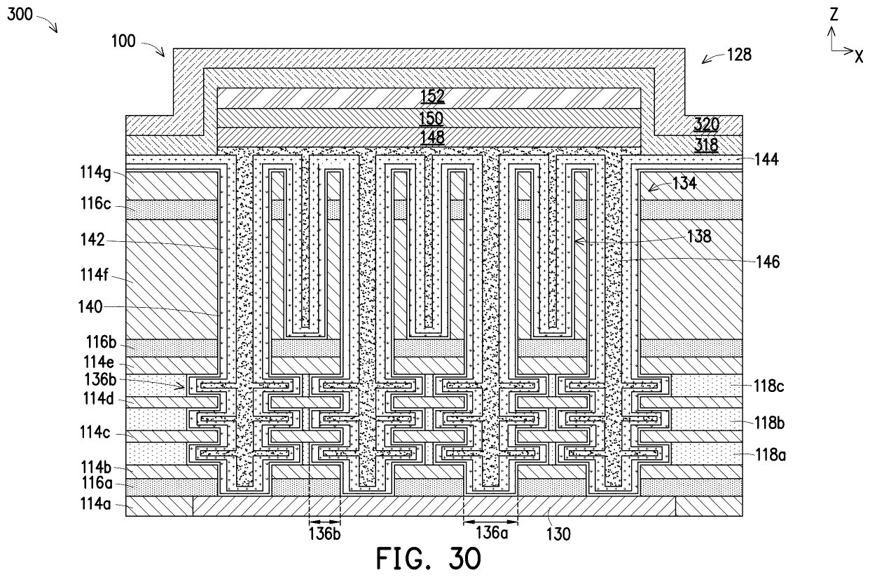

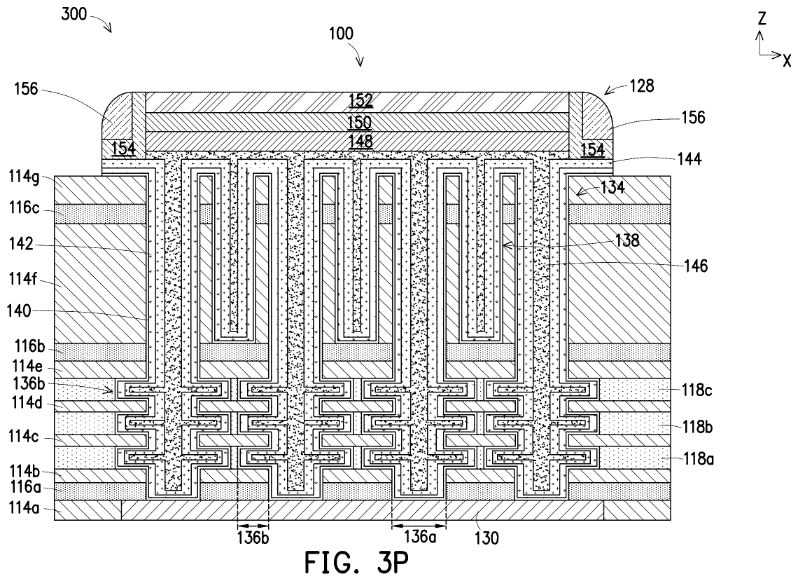

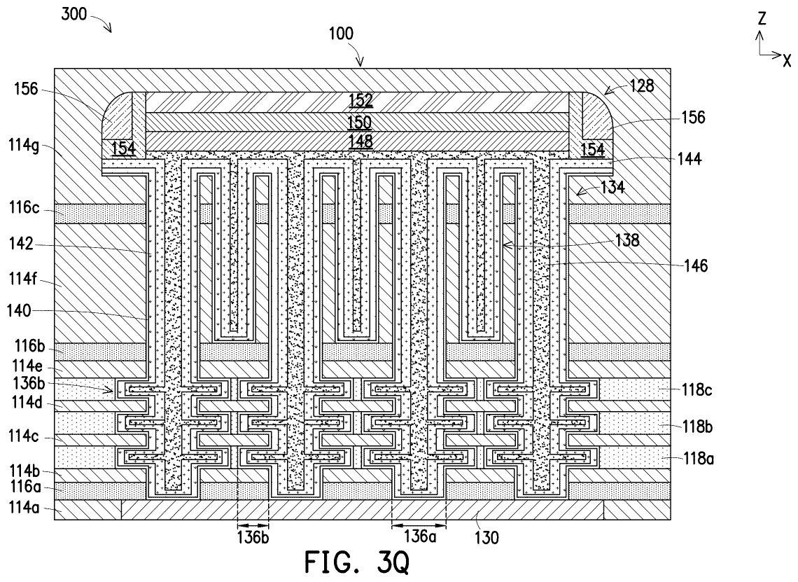

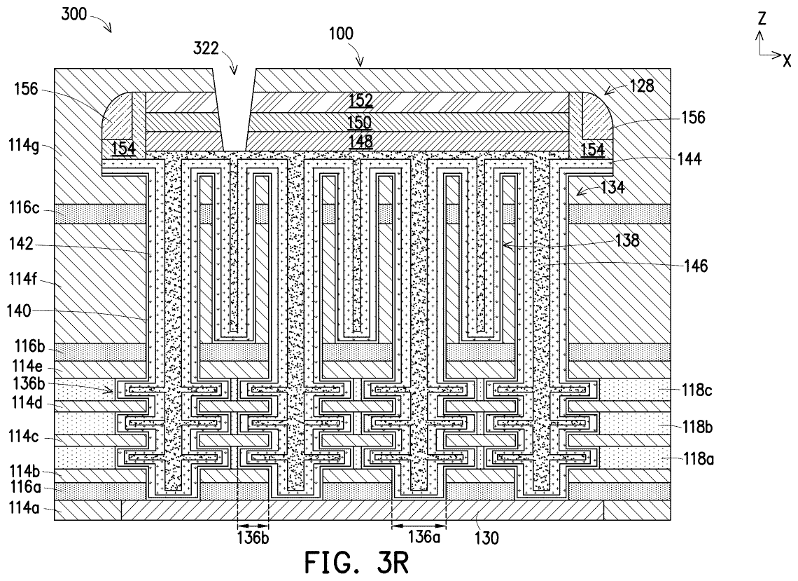

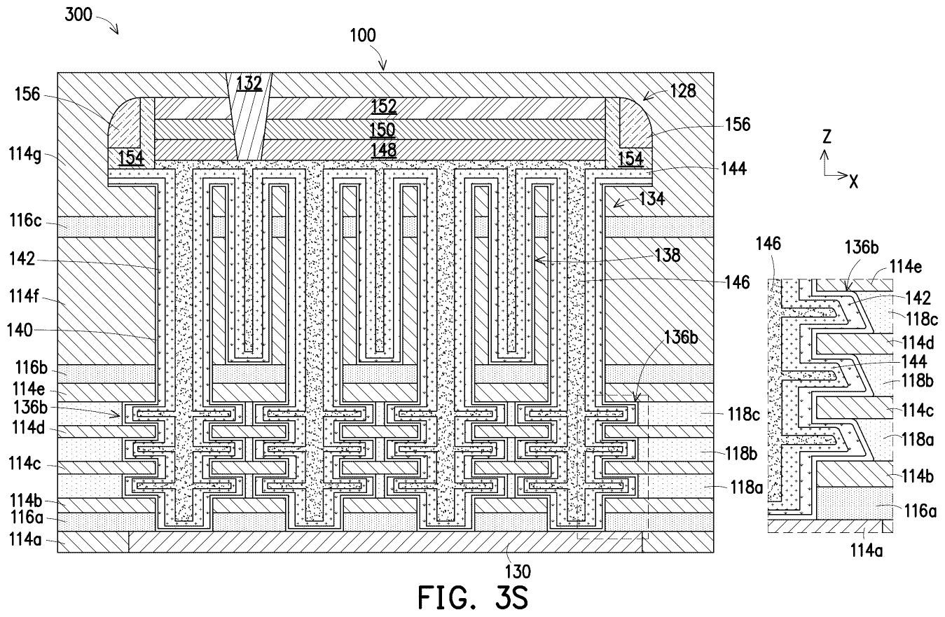

As shown in FIG. 2D, a trench capacitor structure 128 may be formed in one or more dielectric layers in the interconnect layer 104. The trench capacitor structure 128 may be formed such that the first trench structure(s) 134 of the trench capacitor structure 128 land on the bottom contact 130 in the interconnect layer 104. An example process for forming the trench capacitor structure 128 is illustrated and described in connection with FIGS. 3A-3S.

As shown in FIG. 2E, a second portion of the interconnect layer 104 of the semiconductor device 100 is formed above the first portion of the interconnect layer 104, including above the trench capacitor structure 128. The second portion of the interconnect layer 104 may be formed in a similar manner as the first portion of the interconnect layer 104 as described in connection with FIG. 2C. The top contact 132 of the trench capacitor structure 128 may be formed in the second portion of the interconnect layer 104.

As indicated above, FIGS. 2A-2E are provided as an example. Other examples may differ from what is described with regard to FIGS. 2A-2E.

FIGS. 3A-3S are diagrams of an example implementation 300 of forming a trench capacitor structure 128 described herein. In some implementations, one or more of the semiconductor processing operations described in connection with FIGS. 3A-3S may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 3A-3S may be performed as part of the process for forming the semiconductor device 100 described in connection with FIGS. 2A-2E.

As shown in FIG. 3A, the example implementation 300 includes ILD layers 114a-114g, ESLs 116a-116c, and dielectric film layers 118a-118c. In some implementations, in order to permit selective removal (e.g., etching) of portions of the dielectric film layers 118a-118c with respect to the ILD layers 114b-114e to form regions for the fin portions 136b, a material of at least the ILD layers 114b-114e is different from a material of the dielectric film layers 118a-118c.

As shown in FIG. 3B, masking layers may be formed on the ILD layer 114g in the interconnect layer 104 of the semiconductor device 100. For example, a dielectric masking layer 302 may be formed on the ILD layer 114g. The dielectric masking layer 302 may include a silicon oxynitride material (SiON) and/or another suitable dielectric material.

A deposition tool may be used to deposit the dielectric masking layer 302 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 302 after the dielectric masking layer 302 is deposited.

As shown in FIG. 3B, a photoresist layer 304 may be formed above the dielectric masking layer 302, and a pattern 306 may be formed in the photoresist layer 304. A deposition tool may be used to form the photoresist layer on the dielectric masking layer 302 (e.g., using a spin-coating technique or another suitable deposition technique). In some implementations, a bottom antireflective coating (BARC) is first deposited on the dielectric masking layer 302, and then the photoresist layer 304 is deposited onto the BARC. An exposure tool may be used to expose the photoresist layer 304 to a radiation source to pattern the photoresist layer 304. A developer tool may be used to develop and remove portions of the photoresist layer 304 to expose the pattern 306.

As shown in FIG. 3C, an etch tool may be used to etch the dielectric masking layer 302 based on the pattern 306 in the photoresist layer 304, to transfer the pattern 306 to the dielectric masking layer 302. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 302 compared to the material of the underlying ILD layer 114g. Thus, the etch operation may stop on the ILD layer 114g with minimal etching to the ILD layer 114g.

As shown in FIG. 3D, another etch operation is performed to etch through the ILD layers 114b, 114c, 114d, 114c, 114f, and 114g, through the ESLs 116a, 116b, and 116c, and through the dielectric film layers 118a, 118b, and 118c to form a plurality of first trenches 308, which correspond to the first trench structures 134 of the trench capacitor structure 128. The etch operation may include another etch operation in which a different type of etchant is used compared to the etchant that was used to transfer the pattern 306 to the dielectric masking layer 302. Thus, the semiconductor device 100 may be transferred from a first etch tool (in which the pattern 306 was transferred to the dielectric masking layer 302) to a second etch tool (in which the ILD layers 114b, 114c, 114d, 114c, 114f, and 114g, the ESLs 116a, 116b and 116c, and the dielectric film layers 118a, 118b, and 118c are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

The etch operation that is used to etch the ILD layers 114b, 114c, 114d, 114c, 114f, and 114g, the ESLs 116a, 116b, and 116c, and the dielectric film layers 118a, 118b, and 118c, may include a plasma etch operation, a wet chemical etch operation, and/or another type of etch operation that uses an etchant with a higher etch rate for the dielectric materials of the ILD layers 114b, 114c, 114d, 114c, 114f, and 114g, the ESLs 116a, 116b, and 116c, and the dielectric film layers 118a, 118b, and 118c, compared to the etch rate of the dielectric masking layer 302. This enables the ILD layers 114b, 114c, 114d, 114c, 114f, and 114g, the ESLs 116a, 116b, and 116c, and the dielectric film layers 118a, 118b, and 118c, to be etched with minimal etching to the dielectric masking layer 302 (and thus, minimal to no increase in the width or critical dimension at the tops of the first trenches 308). The bottom contact 130 is exposed through the first trenches 308 after the etch operation.

In some implementations, the etch operation that is used to etch the ILD layers 114b, 114c, 114d, 114c, 114f, and 114g, the ESLs 116a, 116b, and 116c, and the dielectric film layers 118a, 118b, and 118c, may include a deep reactive ion etching (RIE) operation that employs multiple cycles. A first cycle includes performing an isotropic etch operation to form the first trenches 308 to a first depth. The etchant in the isotropic etch operation etches a first portion of the dielectric layers to the first depth in an approximately omnidirectional manner based on the pattern 306 that was transferred to the dielectric masking layer 302. The etchant may include sulfur hexafluoride (SF₆) and/or another suitable etchant.

In a deposition operation which is part of the first cycle, a deposition tool may deposit a sidewall protection layer in the first trenches 308. The deposition tool may deposit the sidewall protection layer using a CVD technique, a PVD technique, an ALD technique, or another type of deposition technique. In some implementations, the deposition tool may use a deposition gas, such as perfluorocyclobutane (C₄H₈), to deposit the material of the sidewall protection layer. The sidewall protection layer may include a dielectric material, a polymer material, and/or another suitable material.

In a subsequent etch operation during the first cycle, the sidewall protection layer is removed from bottom surfaces of the first trenches 308. The subsequent etch operation may include performing an anisotropic etch operation (e.g., a directional etch) to remove the sidewall protection layer from the bottom surfaces of the first trenches 308. The highly directional property of the anisotropic etch operation enables the sidewall protection layer to be removed from the bottom surfaces of the first trenches 308 while enabling the sidewall protection layer to remain on the sidewalls of the first trenches 308. The etchant to perform the anisotropic etch operation may include sulfur hexafluoride (SF₆) and/or another suitable etchant.

Subsequently, a second cycle is performed to increase the depth of the first trenches 308 from the first depth to a second depth. In the second cycle, the sidewall protection layer protects sidewalls of the first trenches 308 during an etch operation of the second cycle. This enables the depth of the first trenches 308 to increase from the first depth to the second depth, while minimizing the growth or an increase in the width in the x-direction of the first trenches 308. As a result, the first trenches 308 can be formed using a plurality of cycles to a relatively high aspect ratio. In some implementations, a plurality of the cycles may be performed to form the first trenches 308 to a particular depth, and the quantity of cycles may be selected to achieve a particular depth (e.g., depth D1) and/or a particular aspect ratio.

As shown in FIG. 3E, following the etching of the ILD layers 114b, 114c, 114d, 114c, 114f, and 114g, the ESLs 116a, 116b, and 116c, and the dielectric film layers 118a, 118b, and 118c to form the first trenches 308 and expose the bottom contact 130, the sidewall protection layer is removed. The dielectric film layers 118a, 118b, and 118c may be etched through the first trenches 308 to form lateral extension regions 310. The lateral extension regions 310 laterally extend from the first trenches 308 into the dielectric film layers 118a, 118b, and 118c in the x-direction and/or in the y-direction (e.g., both of which are approximately perpendicular to the z-direction). An etch tool may perform one or more etch cycles in an etch operation (e.g., after an etch operation described above to form the first trenches 308) to form the lateral extension regions 310.

In some implementations, the dielectric film layers 118a, 118b, and 118c may be etched using a buffered oxide etch (BOE) etch technique, in which a BOE etchant includes a combination of hydrofluoric acid (HF) and ammonium fluoride (NH₄F). The concentration of hydrofluoric acid in the BOE etchant may be approximately 1% by volume of approximately 49% strength hydrofluoric acid. However, other values are within the scope of the present disclosure. The concentration of ammonium fluoride in the BOE etchant may be approximately 6% by volume of approximately 40% strength ammonium fluoride. However, other values are within the scope of the present disclosure. In some implementations, the BOE etchant further includes deionized water (DIW). The concentration of deionized water in the BOE etchant may be approximately 7% by volume.

An etch rate of the BOE etchant for the dielectric film layers 118a, 118b, and 118c may be greater than an etch rate of the BOE etchant for the ILD layers 114b, 114c, 114d, and 114c and for the ESL 116a, which results in a greater amount of lateral etching for the dielectric film layers 118a, 118b, and 118c relative to an amount of lateral etching for the ILD layers 114b, 114c, 114d, and 114c, and for the ESL 116a. In this way, the lateral extension regions 310 may extend exclusively or primarily into the dielectric film layers 118a, 118b, and 118c.

Additionally and/or alternatively, a hydrofluoric acid (HF) etchant may be used to etch the dielectric film layers 118a, 118b, and 118c to form the lateral extension regions 310. The HF etchant may include hydrofluoric acid that is diluted in deionized water (DIW). An etch rate of the HF etchant for the dielectric film layers 118a, 118b, and 118c may be greater than an etch rate of the HF etchant for the ILD layers 114b, 114c, 114d, 114c, and for the ESL 116a, which results in a greater amount of lateral etching for the dielectric film layers 118a, 118b, and 118c relative to an amount of lateral etching for the ILD layers 114b, 114c, 114d, 114c, and for the ESL 116a. In this way, the lateral extension regions 310 may extend exclusively or primarily into the dielectric film layers 118a, 118b, and 118c.

A combination of materials for the dielectric film layers 118a, 118b, and 118c, for the ILD layers 114b, 114c, 114d, and 114c, and for the ESL 116a, and the etchant that is used to etch the dielectric film layers 118a, 118b, and 118c to form the extension regions 310, may be selected to generally achieve a greater etch rate for the dielectric film layers 118a, 118b, and 118c than dielectric film layers 118a, 118b, and 118c the etch rate for the ILD layers 114b, 114c, 114d, and 114c, and for the ESL 116a, ILD layers 114b, 114c, 114d, and 114c, and the ESL 116a.

As an example, a BOE etchant may be used in combination with phosphosilicate glass (PSG) layers as the dielectric film layers 118a, 118b, and 118c and borosilicate glass (BSG) layers as the ILD layers 114b, 114c, 114d, and 114e, and the ESL 116a. The etch rate of the BOE etchant for the PSG layers may be greater than the etch rate for the BSG layers, which enables the lateral extension regions 310 to laterally extend into the dielectric film layers 118a, 118b, and 118c. The etch rate for the BOE etchant may be based on a boron concentration in the dielectric film layers 118a, 118b, and 118c and in the ILD layers 114b, 114c, 114d, and 114c, and the ESL 116a. In particular, the etch rate for the BOE etchant may decrease as boron concentration increases, which results in the BSG layers (e.g., the ILD layers 114b, 114c, 114d, and 114c, and the ESL 116a) having a lesser etch rate relative to the PSG layers (e.g., the dielectric film layers 118a, 118b, and 118c).

In some implementations, the etch rate of the BOE etchant for the BSG layers may be included in a range of approximately 420 angstroms per minute to approximately 635 angstroms per minute. However, other values for the range are within the scope of the present disclosure. In some implementations, the etch rate of the BOE etchant for the PSG layers may be included in a range of approximately 3930 angstroms per minute to approximately 8400 angstroms per minute. However, other values for the range are within the scope of the present disclosure.

As another example, a BOE etchant may be used in combination with undoped silicate glass (USG) layers as the dielectric film layers 118a, 118b, and 118c and with borophosphosilicate glass (BPSG) layers as the ILD layers 114b, 114c, 114d, and 114c, and the ESL 116a. The etch rate of the BOE etchant for the USG layers may be greater than the etch rate for the BPSG layers, which enables the lateral extension regions 310 to laterally extend into the dielectric film layers 118a, 118b, and 118c. As another example, a BOE etchant may be used in combination with undoped silicate glass (USG) layers as the dielectric film layers 118a, 118b, and 118c and with borosilicate glass (BSG) layers as the ILD layers 114b, 114c, 114d, and 114c, and the ESL 116a. The etch rate of the BOE etchant for the USG layers may be greater than the etch rate for the BSG layers, which enables the lateral extension regions 310 to laterally extend into the dielectric film layers 118a, 118b, and 118c.

In some implementations, the etch rate of the BOE etchant for the BPSG layers may be included in a range of approximately 840 angstroms per minute to approximately 1480 angstroms per minute. However, other values for the range are within the scope of the present disclosure. In some implementations, the etch rate of the BOE etchant for the USG layers may be included in a range of approximately 1330 angstroms per minute to approximately 6000 angstroms per minute. However, other values for the range are within the scope of the present disclosure.

As another example, a BOE etchant may be used in combination with phosphosilicate glass (PSG) layers as the dielectric film layers 118a, 118b, and 118c and with borophosphosilicate glass (BPSG) layers as the ILD layers 114b, 114c, 114d, and 114c, and the ESL 116a. The etch rate of the BOE etchant for the PSG layers may be greater than the etch rate for the BPSG layers, which enables the lateral extension regions 310 to laterally extend into the dielectric film layers 118a, 118b, and 118c.

As another example, an HF etchant may be used in combination with borophosphosilicate glass (BPSG) as the dielectric film layers 118a, 118b, and 118c and with undoped silicate glass (USG) layers as the ILD layers 114b, 114c, 114d, and 114c, and the ESL 116a. The etch rate of the HF etchant for the BPSG layers may be greater than the etch rate for the USG layers, which enables the lateral extension regions 310 to laterally extend into the dielectric film layers 118a, 118b, and 118c.

As another example, an HF etchant may be used in combination with phosphorsilicate glass (PSG) layers as the dielectric film layers 118a, 118b, and 118c and with undoped silicate glass (USG) layers as the ILD layers 114b, 114c, 114d, and 114e, and the ESL 116a. The etch rate of the HF etchant for the PSG layers may be greater than the etch rate for the USG layers, which enables the lateral extension regions 310 to laterally extend into the dielectric film layers 118a, 118b, and 118c.

As another example, an HF etchant may be used in combination with borophosphosilicate glass (BPSG) layers as the dielectric film layers 118a, 118b, and 118c and with borosilicate glass (BSG) layers as the ILD layers 114b, 114c, 114d, and 114e, and the ESL 116a. The etch rate of the HF etchant for the BPSG layers may be greater than the etch rate for the BSG layers, which enables the lateral extension regions 310 to laterally extend into the dielectric film layers 118a, 118b, and 118c.

As another example, an HF etchant may be used in combination with phosphorsilicate glass (PSG) layers as the dielectric film layers 118a, 118b, and 118c and with borosilicate glass (BSG) layers as the ILD layers 114b, 114c, 114d, and 114e, and the ESL 116a. The etch rate of the HF etchant for the PSG layers may be greater than the etch rate for the BSG layers, which enables the lateral extension regions 310 to laterally extend into the dielectric film layers 118a, 118b, and 118c.

As another example, an HF etchant may be used in combination with silicon nitride (SiₓN_{y}) as the dielectric film layers 118a, 118b, and 118c and with silicon oxide (SiOₓ) layers as the ILD layers 114b, 114c, 114d, and 114e, and the ESL 116a. The etch rate of the HF etchant for the silicon nitride (SiₓN_{y}) layers may be greater than the etch rate for the silicon oxide (SiOₓ) layers, which enables the lateral extension regions 310 to laterally extend into the dielectric film layers 118a, 118b, and 118c.

As another example, an HF etchant may be used in combination with silicon carbide (SiC) as the dielectric film layers 118a, 118b, and 118c and with silicon oxide (SiOₓ) layers as the ILD layers 114b, 114c, 114d, and 114c, and the ESL 116a. The etch rate of the HF etchant for the silicon carbide (SiC) layers may be greater than the etch rate for the silicon oxide (SiOₓ) layers, which enables the lateral extension regions 310 to laterally extend into the dielectric film layers 118a, 118b, and 118c.

In some implementations, a concentration of hydrofluoric acid in the HF etchant may be included in a range of approximately 0.5% by weight of the HF etchant to approximately 10% by weight of the HF etchant to achieve a sufficiently large difference in etch rate (e.g., a sufficiently high etch selectivity) between the dielectric film layers 118a, 118b, and 118c and the ILD layers 114b, 114c, 114d, and 114c, and the ESL 116a. However, other values for the range are within the scope of the present disclosure. In some implementations, the etch rate of the HF etchant for the dielectric film layers 118a, 118b, and 118c may be approximately 3 times greater to approximately 5.3 times greater than the etch rate of the HF etchant for the ILD layers 114b, 114c, 114d, and 114c, and the ESL 116a. However, other values for the range are within the scope of the present disclosure. The etch rate for the HF etchant may be greater for greater concentrations of boron and/or phosphor and less for lesser concentrations of boron and/or phosphor.

The time duration of the etch operation to form the lateral extension regions 310 may be selected to provide sufficient time to fully etch the lateral extension regions 310 while minimizing over etching. As an example, in implementations in which a BOE etchant is used, the time duration for the etch operation may be included in a range of approximately 10 seconds to approximately 30 seconds to provide sufficient time to fully etch the lateral extension regions 310 while minimizing over etching. However, other values for the range are within the scope of the present disclosure. As another example, in implementations in which an HF etchant is used, the time duration for the second etch operation may be included in a range of approximately 10 seconds to approximately 60 seconds to provide sufficient time to fully etch the lateral extension regions 310 while minimizing over etching. However, other values for the range are within the scope of the present disclosure.

As shown in FIG. 3F, a photoresist layer 312 may be formed above the dielectric masking layer 302, and a pattern 314 may be formed in the photoresist layer 304. A deposition tool may be used to form the photoresist layer on the dielectric masking layer 302 (e.g., using a spin-coating technique or another suitable deposition technique). In some implementations, a bottom antireflective coating (BARC) is first deposited on the dielectric masking layer 302, and then the photoresist layer 312 is deposited onto the BARC. An exposure tool may be used to expose the photoresist layer 312 to a radiation source to pattern the photoresist layer 312. A developer tool may be used to develop and remove portions of the photoresist layer 312 to expose the pattern 314.

As shown in FIG. 3G, an etch tool may be used to etch the dielectric masking layer 302 based on the pattern 314 in the photoresist layer 312, to transfer the pattern 314 to the dielectric masking layer 302. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 302 compared to the material of the underlying ILD layer 114g. Thus, the etch operation may stop on the ILD layer 114g with minimal etching to the ILD layer 114g.

As shown in FIG. 3H, another etch operation is performed to etch through the ILD layers 114f and 114g, and through the ESL 116c to form a plurality of second trenches 316, which correspond to the second trench structures 138 of the trench capacitor structure 128. The etch operation may include another etch operation in which a different type of etchant is used compared to the etchant that was used to transfer the pattern 314 to the dielectric masking layer 302. Thus, the semiconductor device 100 may be transferred from a first etch tool (in which the pattern 314 was transferred to the dielectric masking layer 302) to a second etch tool (in which the ILD layers 114f and 114g, and the ESL 116c are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

The etch operation that is used to etch the ILD layers 114f and 114g, and the ESL 116c, may include a plasma etch operation, a wet chemical etch operation, and/or another type of etch operation that uses an etchant with a higher etch rate for the dielectric materials of the ILD layers 114f and 114g, and the ESL 116c, compared to the etch rate of the dielectric masking layer 302. This enables the ILD layers 114f and 114g, and the ESL 116c, to be etched with minimal etching to the dielectric masking layer 302 (and thus, minimal to no increase in the width or critical dimension at the tops of the second trenches 316). The etching stops at the ESL 116b and the ESL 116b is exposed through the second trenches 316 after the etch operation.

In some implementations, similar to the etch operation that is used to form the first trenches 308, the etch operation that is used to etch the ILD layers 114f and 114g, and the ESL 116c to form the second trenches 316, may include a deep reactive ion etching (RIE) operation that employs multiple cycles. A first cycle includes performing an isotropic etch operation to form the second trenches 316 to a first depth. The etchant in the isotropic etch operation etches a first portion of the dielectric layers to the first depth in an approximately omnidirectional manner based on the pattern 314 that was transferred to the dielectric masking layer 302. The etchant may include sulfur hexafluoride (SF₆) and/or another suitable etchant.

In a deposition operation which is part of the first cycle, a deposition tool may deposit a sidewall protection layer in the second trenches 316. The deposition tool may deposit the sidewall protection layer using a CVD technique, a PVD technique, an ALD technique, or another type of deposition technique. In some implementations, the deposition tool may use a deposition gas, such as perfluorocyclobutane (C₄H₈), to deposit the material of the sidewall protection layer. The sidewall protection layer may include a dielectric material, a polymer material, and/or another suitable material.

In a subsequent etch operation during the first cycle, the sidewall protection layer is removed from bottom surfaces of the second trenches 316. The subsequent etch operation may include performing an anisotropic etch operation (e.g., a directional etch) to remove the sidewall protection layer from the bottom surfaces of the second trenches 316. The highly directional property of the anisotropic etch operation enables the sidewall protection layer to be removed from the bottom surfaces of the second trenches 316 while enabling the sidewall protection layer to remain on the sidewalls of the second trenches 316. The etchant to perform the anisotropic etch operation may include sulfur hexafluoride (SF₆) and/or another suitable etchant.

Subsequently, a second cycle may be performed to increase the depth of second trenches 316 from the first depth to a second depth. In the second cycle, the sidewall protection layer protects sidewalls of the second trenches 316 during an etch operation of the second cycle. This enables the depth of the second trenches 316 to increase from the first depth to the second depth, while minimizing the growth or an increase in the width in the x-direction of the second trenches 316. As a result, the second trenches 316 can be formed using a plurality of cycles to a relatively high aspect ratio. In some implementations, a plurality of the cycles may be performed to form the second trenches 316 to a particular depth, and the quantity of cycles may be selected to achieve a particular depth (e.g., depth D2) and/or a particular aspect ratio.

As shown in FIG. 3I, the adhesion layer 140 may be deposited on the sidewalls, on the surfaces of the lateral extension regions 310, on the bottom surfaces of the first trenches 308, and on the sidewalls and on the bottom surfaces of the second trenches 316. The bottom surfaces of the first trenches 308 correspond to the top surface of the bottom contact 130, and thus the adhesion layer 140 may be in physical contact with the top surface of the bottom contact 130. The bottom surfaces of the second trenches 316 correspond to the top surface of the ESL 116b, and thus the adhesion layer 140 may be in physical contact with the top surface of the ESL 116b. In some implementations, a deposition tool is used to conformally deposit the adhesion layer 140 such that the adhesion layer 140 conforms to the profiles of the first trenches 308, the lateral extension regions 310, and the second trenches 316. In some implementations, a conformal CVD technique and/or an ALD technique is used to deposit the adhesion layer 140.

As shown in FIG. 3J, the bottom electrode layer 142 may be deposited on the adhesion layer 140. Thus, the bottom electrode layer 142 is deposited on the sidewalls, on the surfaces of the lateral extension regions 310, and on the bottom surfaces (which correspond to the top surface of the bottom contact 130) of the first trenches 308. The bottom electrode layer 142 may also be deposited on the sidewalls and on the bottom surfaces of the second trenches 316. The second trenches 316 are between adjacent first trenches 308. In some implementations, a deposition tool is used to conformally deposit the bottom electrode layer 142 such that the bottom electrode layer 142 conforms to the profiles of the first trenches 308, the lateral extension regions 310, and the second trenches 316. In some implementations, a conformal CVD technique and/or an ALD technique is used to deposit the bottom electrode layer 142.

As shown in FIG. 3K, the insulator layer 144 may be deposited on the bottom electrode layer 142. Thus, the insulator layer 144 is deposited on the sidewalls, on the surfaces of the lateral extension regions 310, and on the bottom surfaces (which correspond to the top surface of the bottom contact 130) of the first trenches 308. The insulator layer 144 may also be deposited on the sidewalls and on the bottom surfaces of the second trenches 316. The second trenches 316 are between adjacent first trenches 308. In some implementations, a deposition tool is used to conformally deposit the insulator layer 144 such that the insulator layer 144 conforms to the profiles of the first trenches 308, the lateral extension regions 310, and the second trenches 316. In some implementations, a conformal CVD technique and/or an ALD technique is used to deposit the insulator layer 144.

As shown in FIG. 3L, the top electrode layer 146 may be deposited on the insulator layer 144. The top electrode layer 146 may be deposited such that the top electrode layer 146 fills the remaining areas of the first trenches 308 and the second trenches 316. The top electrode layer 146 may also be deposited on the top surface of the insulator layer 144 between adjacent first trenches 308 and second trenches 316. In some implementations, a deposition tool is used to conformally deposit the top electrode layer 146 using a PVD technique, a CVD technique, an ALD technique, and/or another suitable deposition technique.

As shown in FIG. 3M, capping layers are formed above the first trench structures 134 and the second trench structures 138 of the trench capacitor structure 128. For example, the oxide capping layer 148 may be formed above and/or on the top electrode layer 146, the oxynitride capping layer 150 may be formed above and/or on the oxide capping layer 148, and/or the nitride capping layer 152 may be formed above and/or on the oxynitride capping layer 150, among other examples.

A deposition tool may be used to deposit the oxide capping layer 148, the oxynitride capping layer 150, and/or the nitride capping layer 152 using a PVD technique, an ALD technique, a CVD technique, an oxidation technique, and/or another suitable deposition technique. The oxide capping layer 148, the oxynitride capping layer 150, and/or the nitride capping layer 152 may be deposited in one or more deposition operations. In some implementations, a planarization tool may be used to perform a planarization operation (e.g., a CMP operation) to planarize the oxide capping layer 148, the oxynitride capping layer 150, and/or the nitride capping layer 152 after the oxide capping layer 148, the oxynitride capping layer 150, and/or the nitride capping layer 152 is deposited.

As shown in FIG. 3N, the capping layers (e.g., the oxide capping layer 148, the oxynitride capping layer 150, and/or the nitride capping layer 152) may be used to etch and define the top electrode layer 146 of the trench capacitor structure 128. In some implementations, a pattern in a photoresist layer is used to etch the oxide capping layer 148, the oxynitride capping layer 150, and/or the nitride capping layer 152 to form a hard mask over the top electrode layer 146. In these implementations, a deposition tool may be used to form the photoresist layer on the nitride capping layer 152. An exposure tool may be used to expose the photoresist layer to a radiation source to pattern the photoresist layer. A developer tool may be used to develop and remove portions of the photoresist layer to expose the pattern. An etch tool may be used to etch the oxide capping layer 148, the oxynitride capping layer 150, and/or the nitride capping layer 152 based on the pattern to define the hard mask layer. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). An etch tool may then be used to etch the top electrode layer 146 based on the hard mask layer (e.g., based on the pattern in the oxide capping layer 148, the oxynitride capping layer 150, and/or the nitride capping layer 152) to define the top electrode layer 146.

As shown in FIG. 3O, spacer layers 318 and 320 are formed above the capping layers (e.g., the oxide capping layer 148, the oxynitride capping layer 150, and/or the nitride capping layer 152). The spacer layers 318 and 320 extend along the ends of the capping layers (e.g., along the ends of the oxide capping layer 148, the ends of oxynitride capping layer 150, and/or the ends of the nitride capping layer 152) and along the ends of the top electrode layer 146. Moreover, the spacer layers 318 and 320 are formed on the exposed portions of the insulator layer 144.

A deposition tool may be used to deposit the spacer layers 318 and/or 320 using a PVD technique, an ALD technique, a CVD technique, an oxidation technique, and/or another suitable deposition technique. The spacer layers 318 and/or 320 may be deposited in one or more deposition operations. In some implementations, a planarization tool may be used to perform a planarization operation (e.g., a CMP operation) to planarize the spacer layers 318 and/or 310 after the spacer layers 318 and/or 320 are deposited.

As shown in FIG. 3P, the spacer layers 318 and 320 are etched along with portions of the insulator layer 144, portions of the bottom electrode layer 142, and portions of the adhesion layer 140 to define the bottom electrode layer 142 of the MIM structure of the trench capacitor structure 128. The etch operation may be referred to as a CBM etch operation. In some implementations, the etch operation includes a dry etch operation (e.g., a plasma-based etch operation, a gas-based etch operation), a wet chemical etch operation, and/or another type of etch operation. Etching of the spacer layers 318 and 320 removes portions of the spacer layers 318 and 320 from the top of the nitride capping layer 152, resulting information of the sidewall spacers 154 and 156 on the ends of the oxide capping layer 148, the ends of oxynitride capping layer 150, the ends of the nitride capping layer 152, and the ends of the top electrode layer 146. Moreover, etching of the spacer layers 318 and 320 results in the sidewall spacers 156 having rounded outer surfaces.

An etchant (e.g., a gas-based etchant, a plasma-based etchant) may be used to achieve an anisotropic etch of the spacer layers 318 and 320. The spacer layers 318 and 320 may be etched along with portions of the insulator layer 144, portions of the bottom electrode layer 142, and portions of the adhesion layer 140. The anisotropic etch primarily etches in the z-direction in the semiconductor device 100, enabling minimal lateral etching of the bottom electrode layer 142 and of the insulator layer 144 to be achieved.

As shown in FIG. 3Q, additional material of the ILD layer 114g may be formed to encapsulate the trench capacitor structure 128. A deposition tool may be used to deposit the additional material of the ILD layer 114g using a PVD technique, an ALD technique, a CVD technique, an epitaxy technique, an oxidation technique, and/or another suitable deposition technique. The additional material of the ILD layer 114g may be deposited in one or more deposition operations. In some implementations, a planarization tool may be used to perform a planarization operation (e.g., a CMP operation) to planarize the ILD layer 114g after the additional material of the ILD layer 114g is deposited.

As shown in FIG. 3R, a recess 322 may be formed in the ILD layer 114g, through the capping layers 148-152, and to the top electrode layer 146 of the trench capacitor structure 128. Thus, the top electrode layer 146 may be exposed through the recess 322.

In some implementations, a pattern in a photoresist layer is used to etch the ILD layer 114g, the oxide capping layer 148, the oxynitride capping layer 150, and/or the nitride capping layer 152 to form the recess 322. In these implementations, a deposition tool may be used to form the photoresist layer on the ILD layer 114g. An exposure tool may be used to expose the photoresist layer to a radiation source to pattern the photoresist layer. A developer tool may be used to develop and remove portions of the photoresist layer to expose the pattern. An etch tool may be used to etch the ILD layer 114g, the oxide capping layer 148, the oxynitride capping layer 150, and/or the nitride capping layer 152 based on the pattern to form the recess 322. In some implementations, one or more etch operations are performed to etch the ILD layer 114g, the oxide capping layer 148, the oxynitride capping layer 150, and/or the nitride capping layer 152. In some implementations, the one or more etch operations may include a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 322 based on a pattern.

As shown in FIG. 3S, the top contact 132 may be formed in the recess 322. A deposition tool may be used to deposit the material of the top contact 132 using a CVD technique, a PVD technique, an ALD technique, an electroplating technique, and/or another suitable deposition technique. The top contact 132 may be deposited in one or more deposition operations. In some implementations, a seed layer is first deposited, and the top contact 132 is deposited on the seed layer. In some implementations, a planarization tool is used to perform a planarization operation (e.g., a CMP operation) to planarize the top contact 132 after the top contact 132 is deposited.

As shown by the enlarged rectangular portion in FIG. 3S, in an example implementation, fin portions 136b are in the dielectric film layers 118a, 118b, and 118c, with ILD layers 114c and 114d between adjacent fin portions 136b, and ILD layers 114b, 114c, 114d, and 114c over and/or under adjacent fin portions 136b. The fin portions 136b include the MIM structure of the bottom electrode layer 142, the insulator layer 144, and the top electrode layer 146. In some implementations, the fin portions 136b are rectangular, square, approximately rectangular, or approximately square.

As indicated above, FIGS. 3A-3S are provided as an example. Other examples may differ from what is described with regard to FIGS. 3A-3S.

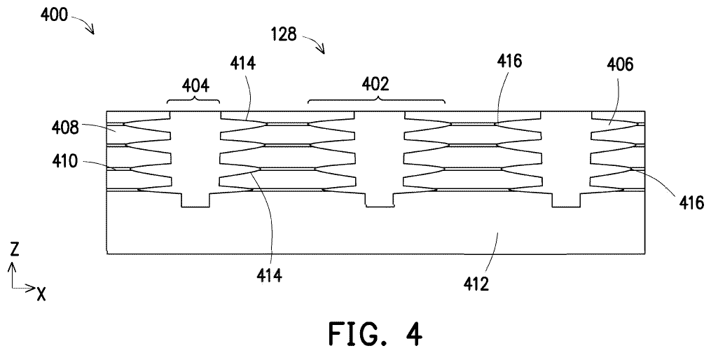

FIG. 4 illustrates example implementation 400 of a portion of a trench capacitor structure 128 with triangular fin portions. Similar to the first trench structures 134, bottom sections of trench structures 402 include a central portion 404 and a plurality of fin portions 406. The fin portions 406 are triangular. Each of the trench structures 402 includes a plurality of fin portions 406 that extend laterally outward from the central portion 404 in the x-direction. The plurality of fin portions 406 extend from the central portion 404 at a bottom section of each trench structure 402. The trench structures 402 are surrounded by an alternating arrangement of ILD layers 408 and dielectric film layers 410. The ILD layers 408 and dielectric film layers 410 may be similar to the ILD layers 114 and dielectric film layers 118. A bottom contact 412, which may be similar to the bottom contact 130, is located under the trench structures 402. Similar to the first trench structures 134, each of the trench structures 402 includes an MIM structure of a bottom electrode layer, an insulator layer, and a top electrode layer.

The fin portions 406 may have angled fin walls 414 such that the fin portions 406 are tapered and terminate at a pointed termination point 416. The fin portions 406 laterally extend from the central portion 404 into the dielectric film layers 410, and/or into the ILD layers 408 in the x-direction. The fin portions 406 may extend primarily into the dielectric film layers 410, and the fin walls 414 are formed in the ILD layers 408, such that the fin walls 414 are ends of the ILD layers 408 that extend inward toward the central portion 404 of a trench structure 402 from the dielectric film layers 410.

In the example implementation 400, the size of the fin portions 406 decreases as a function of depth, with the fin portions 406 at or near the bottom of the trench structures 402 in the z-direction being smaller (e.g., having a smaller lateral width in the x-direction and a smaller thickness in the z-direction) than the fin portions 406 above the fin portions 406 at or near the bottom of the trench structures 402 in the z-direction. The decrease in size as a function of depth may be due to a greater amount of etching to form lateral extension regions for the top fin portions 406 than the amount of etching to form the lateral extension regions for the bottom fin portions 406.

Depending on the materials of the ILD layers 408 and dielectric film layers 410 (or of the ILD layers 114 and dielectric film layers 118), and the etch selectivity of the dielectric film layers 410 with respect to the ILD layers 408 (or the etch selectivity of the dielectric film layers 118 with respect to the ILD layers 114), the fin portions 406 (or fin portions 136b) may have different shapes. For example, the fin portions 136b may be rectangular or square, whereas the fin portions 406 may be triangular.

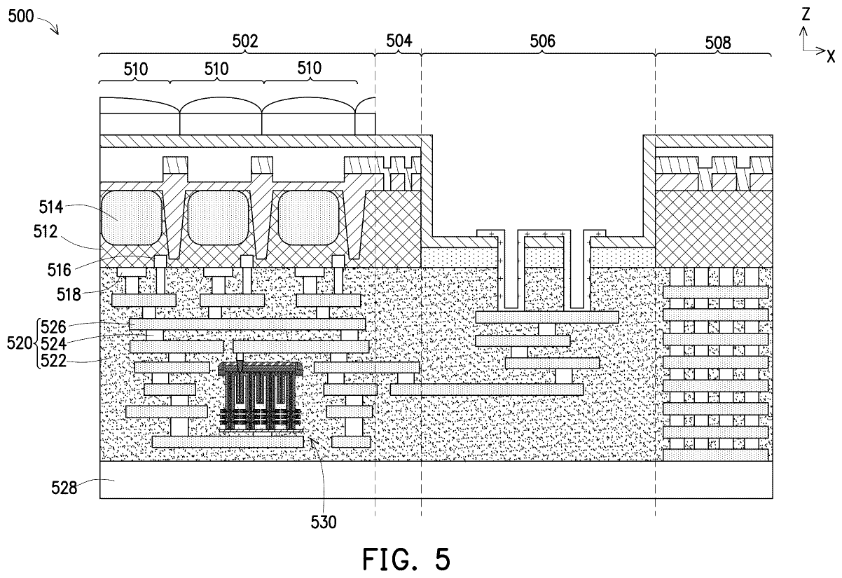

FIG. 5 is a diagram of an example semiconductor device 500 described herein. The semiconductor device 500 may include an example of a three-dimensional image sensor (e.g., a 3D CMOS image sensor). The semiconductor device 500 may be configured to be deployed in various implementations, such as digital cameras, video recorders, night-vision cameras, automotive sensors and cameras, and/or other types of light-sensing implementations.

As shown in FIG. 5, the semiconductor device 500 may include a pixel sensor array 502. The semiconductor device 500 may further include a black level correction (BLC) region 504, a bonding pad region 506, and/or a seal ring region 508, among other examples. The pixel sensor array 502 may include a plurality of pixel sensors 510 arranged in an array. The pixel sensors 510 may be configured to sense incident light and convert photons of the incident light to a photocurrent. The pixel sensors 510 may be included in a device layer 512 of the semiconductor device 500. The pixel sensors 510 may each include one or more photodiodes 514 that are configured to generate a photocurrent based on photons of incident light. The pixel sensors 510 may further include a floating diffusion node 516 in the device layer 512 that is configured to temporarily store the photocurrent generated by an associated pixel sensor 510, and may each include a transfer gate 518 that is configured to control the flow of photocurrent from a photodiode 514 to a floating diffusion node 516. The pixel sensors 510 may be formed by one or more semiconductor processing tools using various semiconductor processing techniques, such as photolithography, etching, deposition, CMP, and/or ion implantation, among other examples.

The BLC region 504 includes a metal shielding layer over a portion of the device layer 512 so that a baseline measurement of current in the device layer 512 in the BLC region 504 can be performed to determine the dark current (e.g., the current in the device layer 512 that is generated from sources other than incident light, such as heat) of the pixel sensor array 502, so that the black level of the pixel sensor array 502 can be adjusted to compensate for the dark current. The bonding pad region 506 may include one or more conductive bonding pads (or c-pads) and/or metallization layers through which electrical connections between the semiconductor device 500 and outside devices and/or external packaging may be established. The seal ring region 508 may include an arrangement of metallization structures and interconnect structures to provide structural rigidity for the semiconductor device 500 and to protect the semiconductor device 500 from ingress of humidity and other contaminants.

As further shown in FIG. 5, the semiconductor device 500 may include an interconnect layer 520 under the device layer 512. The interconnect layer 520 may include a dielectric region 522 that includes one or more dielectric layers (e.g., ILD layers, intermetal dielectric (IMD) layers, ESLs) and an arrangement of metallization structures 524 and interconnect structures 526 in the dielectric region 522. A passivation layer 528 may be included under the interconnect layer 520.

As further shown in FIG. 5, one or more overflow capacitors 530 may be included in the interconnect layer 520. The overflow capacitor(s) 530 may be structurally implemented as the trench capacitor structure 128 illustrated and described herein. An overflow capacitor 530 may be electrically coupled to a floating diffusion node 516 of a pixel sensor 510 and may be configured to store overflow photocurrent from the floating diffusion node 516.

As indicated above, FIG. 5 is provided as an example. Other examples may differ from what is described with regard to FIG. 5.

FIG. 6 is a flowchart of an example process 600 associated forming a semiconductor device. In some implementations, one or more process blocks of FIG. 6 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 6, process 600 may include forming a trench through a plurality of dielectric layers (block 610). For example, one or more semiconductor processing tools may be used to form a trench (e.g., first trench 308) through a plurality of dielectric layers (e.g., ILD layers 114b-114g, ESLs 116a-116c, dielectric film layers 118a-118c), as described herein. In some implementations, the plurality of dielectric layers includes one or more upper dielectric layers (e.g., ESLs 116b and 116c, ILD layers 114f and 114g) and a plurality of lower dielectric layers (e.g., ESL 116a, ILD layers 114b-114c, dielectric film layers 118a-118c). In some implementations, the plurality of lower dielectric layers are under the one or more upper dielectric layers in a first direction (e.g., z-direction) in a semiconductor device, and the plurality of lower dielectric layers includes a first plurality of lower dielectric layers (e.g., dielectric film layers 118a-118c) and a second plurality of lower dielectric layers (e.g. ILD layers 114b-114c) arranged in an alternating configuration in the first direction.

As further shown in FIG. 6, process 600 may include forming a plurality of lateral extension regions that laterally extend from the trench and into the first plurality of lower dielectric layers in a second direction approximately perpendicular to the first direction (block 620). For example, one or more semiconductor processing tools may be used to form a plurality of lateral extension regions (e.g., lateral extension regions 310) that laterally extend from the trench and into the first plurality of lower dielectric layers in a second direction (e.g., x-direction) approximately perpendicular to the first direction, as described herein.

As further shown in FIG. 6, process 600 may include forming, along surfaces of the trench and along surfaces of the plurality of lateral extension regions, a first conductive layer of a semiconductor structure (block 630). For example, one or more semiconductor processing tools may be used to form, along surfaces of the trench and along surfaces of the plurality of lateral extension regions, a first conductive layer (e.g., bottom electrode layer 142) of a semiconductor structure (e.g., trench capacitor structure 128), as described herein.

As further shown in FIG. 6, process 600 may include forming an insulator layer of the semiconductor structure on the first conductive layer (block 640). For example, one or more semiconductor processing tools may be used to form an insulator layer (e.g., insulator layer 144) of the semiconductor structure on the first conductive layer, as described herein.

As further shown in FIG. 6, process 600 may include forming a second conductive layer of the semiconductor structure on the insulator layer (block 650). For example, one or more semiconductor processing tools may be used to form a second conductive layer (e.g. top electrode layer 146) of the semiconductor structure on the insulator layer, as described herein.

Process 600 may include additional implementations, such as any single implementation or any combination of implementations described below and/or in connection with one or more other processes described elsewhere herein.

In a first implementation, forming the trench includes performing a first etch operation to form the trench, and forming the plurality of lateral extension regions includes performing, after the first etch operation, a second etch operation to selectively etch the first plurality of lower dielectric layers with respect to the second plurality of lower dielectric layers, to form the plurality of lateral extension regions.

In a second implementation, alone or in combination with the first implementation, the second etch operation is performed using an etchant that etches the first plurality of lower dielectric layers at a first etch rate and the second plurality of lower dielectric layers at a second etch rate, and the first etch rate is greater than the second etch rate.

In a third implementation, alone or in combination with one or more of the first and second implementations, the first plurality of lower dielectric layers includes a plurality of silicon nitride layers or a plurality of silicon carbide layers, and the second plurality of lower dielectric layers includes a plurality of silicon oxide layers.

In a fourth implementation, alone or in combination with one or more of the first through third implementations, process 600 includes forming an additional trench (e.g., second trench 316) laterally adjacent to a side of the trench in the second direction, where a bottom of the additional trench includes a surface of an upper dielectric layer (e.g., ESL 116b) of the one or more upper dielectric layers, and where the bottom of the additional trench is above the plurality of lateral extension regions in the first direction.

In a fifth implementation, alone or in combination with one or more of the first through fourth implementations, the forming of the additional trench is performed prior to the forming of the first conductive layer, the insulator layer, and the second conductive layer, and the first conductive layer, the insulator layer, and the second conductive layer are formed along surfaces of the additional trench.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

In this way, a DTC structure is provided where conductive electrode layers and an insulator layer of the DTC structure extend laterally into a plurality of dielectric layers. The plurality of dielectric layers may be in an alternating arrangement. In addition, the conductive electrode layers and the insulator layer of the DTC structure may extend laterally into one or more of the dielectric layers. The lateral extensions of the conductive electrode layers and the insulator layer into the one or more dielectric layers may be referred to as fin portions of the DTC structure. The fin portions may extend laterally outward from a central portion of a trench structure at a bottom section of the trench structure. The DTC structure may include a plurality of trench structures, and each trench structure may include a respective set of fin portions that extend laterally outward from the trench structure. In addition to the trench structures that include fin portions, in some implementations described herein, the DTC structure includes additional trench structures that are located laterally between top sections of adjacent trench structures that include fin portions. The depth of the additional trench structures is less than a depth of the trench structures that include fin portions. This enables the fin portions to extend laterally under the additional trench structures, which enables the size of the fin portions to be increased. The fin portions and additional trench structures enable the surface area of the conductive electrode layers to be increased (e.g., relative to the conductive electrode layers in one type of trench structure extending vertically through the dielectric layers), which may increase the capacitance of the DTC structure with minimal increase to the overall footprint of the DTC structure.

As described in greater detail above, some implementations described herein provide a semiconductor device. The semiconductor device includes a plurality of dielectric layers that are arranged in a first direction and extend in a second direction approximately perpendicular to the first direction. The semiconductor device includes a semiconductor structure that extends through the plurality of dielectric layers, where the semiconductor structure includes a trench structure including a central portion that extends in the first direction through the plurality of dielectric layers, and a plurality of fin portions that extend laterally outward from the central portion in the second direction, and where the plurality of fin portions extend from the central portion at a bottom section of the trench structure.

As described in greater detail above, some implementations described herein provide a method. The method includes forming a trench through a plurality of dielectric layers, where the plurality of dielectric layers includes one or more upper dielectric layers and a plurality of lower dielectric layers, and where the plurality of lower dielectric layers are under the one or more upper dielectric layers in a first direction in a semiconductor device, and the plurality of lower dielectric layers includes a first plurality of lower dielectric layers and a second plurality of lower dielectric layers arranged in an alternating configuration in the first direction. The method includes forming a plurality of lateral extension regions that laterally extend from the trench and into the first plurality of lower dielectric layers in a second direction approximately perpendicular to the first direction. The method includes forming, along surfaces of the trench and along surfaces of the plurality of lateral extension regions, a first conductive layer of a semiconductor structure. The method includes forming an insulator layer of the semiconductor structure on the first conductive layer. The method includes forming a second conductive layer of the semiconductor structure on the insulator layer.

As described in greater detail above, some implementations described herein provide a semiconductor structure. The semiconductor structure includes a plurality of first trench structures that extend through a plurality of dielectric layers in a first direction, where the plurality of first trench structures are spaced apart from each other along a second direction approximately perpendicular to the first direction, where each of the plurality of first trench structures includes a plurality of extended width regions at a bottom section of each of the plurality of first trench structures, where the plurality of extended width regions extend a width of each of the plurality of first trench structures in the second direction. The semiconductor structure includes a plurality of second trench structures that extend through a subset of the plurality of dielectric layers in the first direction, where respective second trench structures of the plurality of second trench structures are between adjacent first trench structures of the plurality of first trench structures.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of dielectric layers that are arranged in a first direction and extend in a second direction approximately perpendicular to the first direction; and
a semiconductor structure that extends through the plurality of dielectric layers,
wherein the semiconductor structure comprises:
a trench structure comprising a central portion that extends in the first direction through the plurality of dielectric layers, and a plurality of fin portions that extend laterally outward from the central portion in the second direction, and
wherein the plurality of fin portions extend from the central portion at a bottom section of the trench structure.

2. The semiconductor device of claim 1, wherein a first set of the plurality of fin portions extend from a first side of the central portion;
wherein a second set of the plurality of fin portions extend from a second side of the central portion; and
wherein the first side is opposite the second side.

3. The semiconductor device of claim 1, further comprising a metal contact below the trench structure in the first direction, wherein the bottom section of the trench structure is adjacent to the metal contact.

4. The semiconductor device of claim 1, wherein the semiconductor structure further comprises an additional trench structure laterally adjacent to a side of the trench structure in the second direction; and
wherein a depth of the additional trench structure in the first direction is less than a depth of the trench structure in the first direction.

5. The semiconductor device of claim 4, wherein a bottom of the additional trench structure is above the plurality of fin portions.

6. The semiconductor device of claim 5, wherein the bottom of the additional trench structure is on a dielectric layer of the plurality of dielectric layers.

7. The semiconductor device of claim 4, wherein the additional trench structure has a linear profile along the depth of the additional trench structure in the first direction from a top of the additional trench structure to a bottom of the additional trench structure.

8. The semiconductor device of claim 4, further comprising:
a first conductive layer in the trench structure and in the additional trench structure;
an insulator layer on the first conductive layer in the trench structure and additional trench structure; and
a second conductive layer on the insulator layer in the trench structure and additional trench structure,
wherein the first conductive layer, the insulator layer, and the second conductive layer extend from the trench structure to the additional trench structure.

9. The semiconductor device of claim 1, wherein the plurality of dielectric layers comprises a first plurality of dielectric layers alternately stacked in the first direction with a second plurality of dielectric layers;
wherein a material of the first plurality of dielectric layers is different from a material of the second plurality of dielectric layers; and
wherein the plurality of fin portions are in respective dielectric layers of the first plurality of dielectric layers.

10. The semiconductor device of claim 1, wherein the plurality of fin portions are at least one of square or rectangular.

11. A method, comprising:
forming a trench through a plurality of dielectric layers,
wherein the plurality of dielectric layers comprises one or more upper dielectric layers and a plurality of lower dielectric layers, and
wherein the plurality of lower dielectric layers are under the one or more upper dielectric layers in a first direction in a semiconductor device, and the plurality of lower dielectric layers comprises a first plurality of lower dielectric layers and a second plurality of lower dielectric layers arranged in an alternating configuration in the first direction;
forming a plurality of lateral extension regions that laterally extend from the trench and into the first plurality of lower dielectric layers in a second direction approximately perpendicular to the first direction;
forming, along surfaces of the trench and along surfaces of the plurality of lateral extension regions, a first conductive layer of a semiconductor structure;
forming an insulator layer of the semiconductor structure on the first conductive layer; and
forming a second conductive layer of the semiconductor structure on the insulator layer.

12. The method of claim 11, wherein forming the trench comprises:
performing a first etch operation to form the trench; and
wherein forming the plurality of lateral extension regions comprises:
performing, after the first etch operation, a second etch operation to selectively etch the first plurality of lower dielectric layers with respect to the second plurality of lower dielectric layers, to form the plurality of lateral extension regions.

13. The method of claim 12, wherein the second etch operation is performed using an etchant that etches the first plurality of lower dielectric layers at a first etch rate and the second plurality of lower dielectric layers at a second etch rate; and
wherein the first etch rate is greater than the second etch rate.

14. The method of claim 12, wherein the first plurality of lower dielectric layers comprises a plurality of silicon nitride layers or a plurality of silicon carbide layers; and
wherein the second plurality of lower dielectric layers comprises a plurality of silicon oxide layers.

15. The method of claim 11, further comprising:
forming an additional trench laterally adjacent to a side of the trench in the second direction,
wherein a bottom of the additional trench comprises a surface of an upper dielectric layer of the one or more upper dielectric layers, and
wherein the bottom of the additional trench is above the plurality of lateral extension regions in the first direction.

16. The method of claim 15, wherein the forming of the additional trench is performed prior to the forming of the first conductive layer, the insulator layer, and the second conductive layer; and
wherein the first conductive layer, the insulator layer, and the second conductive layer are formed along surfaces of the additional trench.

17. A semiconductor structure, comprising:
a plurality of first trench structures that extend through a plurality of dielectric layers in a first direction,
wherein the plurality of first trench structures are spaced apart from each other along a second direction approximately perpendicular to the first direction,
wherein each of the plurality of first trench structures includes a plurality of extended width regions at a bottom section of each of the plurality of first trench structures,
wherein the plurality of extended width regions extend a width of each of the plurality of first trench structures in the second direction; and
a plurality of second trench structures that extend through a subset of the plurality of dielectric layers in the first direction,
wherein respective second trench structures of the plurality of second trench structures are between adjacent first trench structures of the plurality of first trench structures.

18. The semiconductor structure of claim 17, wherein the plurality of first trench structures extend to a greater depth in the first direction than a depth of the plurality of second trench structures in the first direction.

19. The semiconductor structure of claim 17, wherein the plurality of extended width regions are in respective dielectric layers of the plurality of dielectric layers; and
wherein the respective dielectric layers of the plurality of dielectric layers are in a stacked arrangement in the first direction.

20. The semiconductor structure of claim 19, wherein the stacked arrangement is below bottom surfaces of the plurality of second trench structures.
